(19) United States
(12) Patent Application Publication
(10) Pub. No.: US 2025/0187903 A1
(43) Pub. Date: Jun. 12, 2025

(54) Piezoelectric Motion Limiters for MEMS Autofocus Actuator

(71) Applicant: MEMS DRIVE (Nanjing) Co., Ltd., Nanjing (CN)

(72) Inventor: Matthew NG, Rosemead, CA (US)

(73) Assignee: MEMS DRIVE (Nanjing) Co., Ltd., Nanjing (CN)

(21) Appl. No.: 18/970,809

(22) Filed: Dec. 5, 2024

Related U.S. Application Data
(60) Provisional application No. 63/607,287, filed on Dec. 7, 2023.
(60) Provisional application No. 63/568,646, filed on Mar. 22, 2024.

(51) Int. Cl. B81B 3/00; G03B 13/36; H04N 23/67

(52) U.S. Cl. CPC B81B 3/0051; G03B 13/36; H04N 23/67; B81B 2203/0136; B81B 2203/0163; B81B 2203/0172; B81B 2203/051; B81B 2203/053

(57) ABSTRACT

A micro-electrical-mechanical system (MEMS) piezoelectric autofocus actuator includes: a fixed stage that is stationary; a moving stage that is movable along a travel direction (Z-axis); a motion control system coupling the fixed stage to the moving stage and including motion control springs; piezoelectric bending elements configured to deform the motion control system and thereby control a precise position of the moving stage relative to the fixed stage; and integrated piezoelectric motion stops that are actuatable to restrict out-of-plane motion of the moving stage along the travel direction (Z-axis). In another example, a MEMS piezoelectric autofocus actuator includes integrated motion limiting snubbers configured to limit in-plane motion of the moving stage; integrated motion stoppers configured to restrict out-of-plane motion of the moving stage along the travel direction (Z-axis); and assembled motion stoppers disposed in assembly slots and configured to restrict out-of-plane motion of the moving stage along the travel direction (Z-axis).

### CROSS-REFERENCE TO RELATED APPLICATION

This application claims the benefit of U.S. Provisional Application No. 63/607,287 filed on Dec. 7, 2023, and U.S. Provisional Application No. 63/568,646 filed on Mar. 22, 2024, the entire contents of which are incorporated herein by reference.

### FIELD OF THE DISCLOSURE

This disclosure relates to piezoelectric motion limiting features for actuatable MEMS devices, and more particularly, to MEMS piezoelectric autofocus actuators with integrated in-plane motion limiting snubbers, integrated out-of-plane motion stoppers, assembled out-of-plane motion stoppers, and/or combinations thereof for restricting motion of a moving stage along a direction of travel.

### BACKGROUND

As is known in the art, actuators may be used to convert electronic signals into mechanical motion. In many applications such as, e.g., portable devices, imaging-related devices, telecommunications components, and medical instruments, it may be beneficial for miniature actuators to fit within the small size, low power, and cost constraints of these application.

Micro-electrical-mechanical system (MEMS) technology is a technology that, in its most general form, may be defined as miniaturized mechanical and electro-mechanical elements that are made using the techniques of microfabrication. The critical dimensions of MEMS devices may vary from well below one micron to several millimeters. In general, MEMS actuators are more compact than conventional actuators, and they consume less power.

### SUMMARY

According to an aspect of the present disclosure, a micro-electrical-mechanical system (MEMS) piezoelectric autofocus actuator is provided. The MEMS piezoelectric autofocus actuator includes: a fixed stage that is stationary; a moving stage that is movable along a travel direction (Z-axis); a motion control system coupling the fixed stage to the moving stage and including a plurality of motion control springs; a plurality of piezoelectric bending elements configured to deform the motion control system and thereby control a precise position of the moving stage relative to the fixed stage; and a plurality of integrated piezoelectric motion stops that are actuatable to restrict out-of-plane motion of the moving stage along the travel direction (Z-axis).

In some examples, the integrated piezoelectric motion stops are disposed along outer peripheral edges of the fixed stage. In some examples, the fixed stage comprises a MEMS outer frame and a MEMS inner frame.

In some examples, the integrated piezoelectric motion stops include: a motion stop subframe, wherein the motion stop subframe is integrated with the MEMS outer frame of the fixed stage; a deployment lock spring connected to the motion stop subframe; a deployment lock connected to the deployment lock spring; a deployment hinge disposed on the motion stop subframe; a deployment pad that is rotatable about the deployment hinge to a deployed position; one or more piezoelectric hinges connected to the deployment pad; and a locking block connected to the one or more piezoelectric hinges, wherein the locking block is actuatable via the one or more piezoelectric hinges to restrict the out-of-plane motion of the moving stage when in the deployed position. The deployment lock is configured to hold the deployment pad in place when in the deployed position.

In some examples, after the deployment pad is rotated about the deployment hinge to the deployed position, the integrated piezoelectric motion stops are reinforced by applying epoxy to encapsulate the deployment lock, the deployment lock spring, the deployment hinge, a surface of the deployment pad, and at least part of a surrounding surface of the motion stop subframe.

In some examples, to restrict the out-of-plane motion of the moving stage along the travel direction (Z-axis) of the moving stage, a voltage is applied to the one or more piezoelectric hinges to actuate the integrated piezoelectric motion stops, causing the one or more piezoelectric hinges to bend and thereby move the locking block to a locked position in which the locking block engages with a surface of the moving stage to restrict the out-of-plane motion thereof.

In some examples, the MEMS outer frame has electrical contact pads disposed thereon, and the voltage is applied to the electrical contact pads disposed on the MEMS outer frame of the fixed stage to actuate the one or more piezoelectric hinges and move the locking block to the locked position.

In some examples, to allow the out-of-plane motion of the moving stage along the travel direction (Z-axis) of the moving stage, a voltage is applied to the one or more piezoelectric hinges to actuate the integrated piezoelectric motion stops, causing the one or more piezoelectric hinges to straighten and thereby move the locking block to an unlocked position in which the locking block does not engage with the moving stage to allow the out-of-plane motion thereof.

In some examples, the MEMS piezoelectric autofocus actuator includes a plurality of MEMS electrical connection flexures connecting the fixed stage to the moving stage. In some examples, the plurality of piezoelectric bending elements include a plurality of MEMS piezoelectric bending films.

According to another aspect of the present disclosure, a micro-electrical-mechanical system (MEMS) piezoelectric autofocus actuator is provided, which includes: a fixed stage that is stationary; a moving stage that is movable along a travel direction (Z-axis), wherein the moving stage has a plurality of assembly slots disposed thereon; a motion control system coupling the fixed stage to the moving stage and including a plurality of motion control springs; a plurality of piezoelectric bending elements configured to deform the motion control system and thereby control a precise position of the moving stage relative to the fixed stage; a plurality of integrated motion limiting snubbers configured to limit in-plane motion of the moving stage; a plurality of integrated motion stoppers configured to restrict out-of-plane motion of the moving stage along the travel direction (Z-axis); and a plurality of assembled motion stoppers disposed in the plurality of assembly slots and configured to restrict out-of-plane motion of the moving stage along the travel direction (Z-axis).

In some examples, the integrated motion limiting snubbers include: a snubber subframe, wherein the snubber subframe is integrated in a MEMS inner frame of the fixed stage; a locking spring connected to the snubber subframe; a locking bolt connected to the locking spring; a twisting hinge disposed on the snubber subframe; and a snubbing pad with a snubbing arm that is rotatable about the twisting hinge to a deployed position. The snubbing pad with the snubbing arm is configured to limit the in-plane motion of the moving stage when in the deployed position.

In some examples, the integrated motion stoppers include: a stopper subframe, wherein the stopper subframe is integrated in a MEMS inner frame of the fixed stage; a locking spring connected to the stopper subframe; a locking bolt connected to the locking spring; a twisting hinge disposed on the stopper subframe; a stopper pad that is rotatable about the twisting hinge to a deployed position; one or more piezoelectric hinges connected to the stopper pad; and a Z-stop block connected to the one or more piezoelectric hinges. The Z-stop block is actuatable via the one or more piezoelectric hinges to restrict the out-of-plane motion of the moving stage when in the deployed position.

In some examples, to restrict the out-of-plane motion of the moving stage along the travel direction (Z-axis) of the moving stage, a voltage is applied to the one or more piezoelectric hinges to actuate the integrated motion stoppers, causing the one or more piezoelectric hinges to bend and thereby move the Z-stop block to a locked position in which the Z-stop block engages with a surface of the moving stage to restrict the out-of-plane motion thereof.

In some examples, the assembled motion stoppers include: a stopper body that is stationary; one or more piezoelectric hinges connected to the stopper body; and a locking block connected to the one or more piezoelectric hinges. The locking block is actuatable via the one or more piezoelectric hinges to restrict the out-of-plane motion of the moving stage when in the deployed position.

In some examples, to restrict the out-of-plane motion of the moving stage along the travel direction (Z-axis) of the moving stage, a voltage is applied to the one or more piezoelectric hinges to actuate the assembled motion stoppers, causing the one or more piezoelectric hinges to bend and thereby move the locking block to a locked position in which the locking block engages with a surface of the moving stage to restrict the out-of-plane motion thereof.

According to yet another aspect of the present disclosure, a micro-electrical-mechanical system (MEMS) piezoelectric autofocus actuator is provided, which includes: a fixed stage that is stationary; a moving stage that is movable along a travel direction (Z-axis); a motion control system coupling the fixed stage to the moving stage and including a plurality of motion control springs; a plurality of piezoelectric bending elements configured to deform the motion control system and thereby control a precise position of the moving stage relative to the fixed stage; an alignment substrate having a plurality of assembly slots; and a plurality of assembled piezoelectric motion stops disposed in the plurality of assembly slots of the alignment substrate, wherein the assembled piezoelectric motion stops are configured to be actuated to restrict out-of-plane motion of the moving stage along the travel direction (Z-axis) thereof.

In some examples, the assembled piezoelectric motion stops include: a pair of electrical contact pads; a motion stop body; a locking block; and a piezoelectric hinge connecting the motion stop body and the locking block. The locking block is actuatable via the piezoelectric hinge to restrict the out-of-plane motion of the moving stage.

In some examples, to restrict the out-of-plane motion of the moving stage along the travel direction (Z-axis) of the moving stage, a voltage differential is applied between the electrical contact pads to actuate the assembled piezoelectric motion stops, causing the piezoelectric hinge to bend and thereby move the locking block to a locked position in which the locking block engages with a surface of the moving stage to restrict the out-of-plane motion thereof.

### BRIEF DESCRIPTION OF THE DRAWINGS

The embodiments of the present disclosure will be understood and appreciated more fully from the following description when taken in conjunction with the drawings, in which:

FIG. 1A is a perspective view of a MEMS camera module in accordance with various embodiments of the present disclosure;

FIG. 1B is a diagrammatic view of an in-plane MEMS actuator with an optoelectronic device in accordance with various embodiments of the present disclosure;

FIG. 1C is a perspective view of an in-plane MEMS actuator with the optoelectronic device in accordance with various embodiments of the present disclosure;

FIG. 2A is a diagrammatic view of an in-plane MEMS actuator in accordance with various embodiments of the present disclosure;

FIG. 2B is a diagrammatic view of a comb drive sector in accordance with various embodiments of the present disclosure;

FIG. 2C is a diagrammatic view of a comb pair in accordance with various embodiments of the present disclosure;

FIG. 2D is a diagrammatic view of fingers of the comb pair of FIG. 2C in accordance with various embodiments of the present disclosure;

FIG. 3A is a diagrammatic view of a MEMS package in accordance with various embodiments of the present disclosure;

FIGS. 3B-3D are diagrammatic views of a piezoelectric out-of-plane actuator in accordance with various embodiments of the present disclosure;

FIG. 3E is a diagrammatic view of a piezoelectric in-plane actuator in accordance with various embodiments of the present disclosure;

FIG. 4A is a diagrammatic view of a MEMS image sensor assembly in accordance with various embodiments of the present disclosure;

FIG. 4B is an exploded diagrammatic view of a MEMS image sensor assembly in accordance with various embodiments of the present disclosure;

FIG. 4C is a cross-sectional view of an electromagnetic actuator assembled as part of the MEMS image sensor assembly of FIGS. 4A-4B, with a magnetic flux graph imposed over the cross-section;

FIG. 5A is a diagrammatic view of an electrically-conductive, MEMS flexure assembly in an unlatched configuration in accordance with various embodiments of the present disclosure;

FIG. 5B is a diagrammatic view of an electrically-conductive, MEMS flexure assembly in a latched configuration in accordance with various embodiments of the present disclosure;

FIG. 5C is a diagrammatic view of a latch assembly of the electrically-conductive, MEMS flexure assembly of FIG. 5A in the unlatched configuration in accordance with various embodiments of the present disclosure;

FIG. 5D is a diagrammatic view of a latch assembly of the electrically-conductive, MEMS flexure assembly of FIG. 5B in the latched configuration in accordance with various embodiments of the present disclosure;

FIG. 6A is diagrammatic view of a piezoelectric autofocus actuator, as fabricated, in accordance with various embodiments of the present disclosure;

FIG. 6B is diagrammatic view of the piezoelectric autofocus actuator, as assembled and latched, in accordance with various embodiments of the present disclosure;

FIG. 6C is diagrammatic view of the piezoelectric autofocus actuator with the moving stage moving to a positive Z travel position in accordance with various embodiments of the present disclosure;

FIG. 6D is diagrammatic view of the piezoelectric autofocus actuator with the moving stage being locked in the positive Z travel position in accordance with various embodiments of the present disclosure;

FIG. 7A is diagrammatic view of an integrated in-plane motion limiting snubber prior to deployment in accordance with various embodiments of the present disclosure;

FIG. 7B is diagrammatic view of the integrated in-plane motion limiting snubber after deployment in accordance with various embodiments of the present disclosure;

FIG. 8A is diagrammatic view of an integrated out-of-plane motion stopper as fabricated prior to deployment in accordance with various embodiments of the present disclosure;

FIG. 8B is diagrammatic view of the integrated out-of-plane motion stopper after deployment in accordance with various embodiments of the present disclosure;

FIG. 8C is diagrammatic view of the integrated out-of-plane motion stopper in the engaged (locked) position after actuation in accordance with various embodiments of the present disclosure;

FIG. 9A is a top view of an out-of-plane motion stopper in accordance with various embodiments of the present disclosure;

FIG. 9B is a side view and a perspective view of the out-of-plane motion stopper in accordance with various embodiments of the present disclosure;

FIG. 9C is a side view and a perspective view of the out-of-plane motion stopper in the engaged (locked) position after actuation in accordance with various embodiments of the present disclosure;

FIG. 9D is a diagrammatic view of an assembly slot disposed in the moving stage in accordance with various embodiments of the present disclosure;

FIG. 9E is a diagrammatic view of the out-of-plane motion stopper assembled in the assembly slot of the moving stage in accordance with various embodiments of the present disclosure;

FIGS. 9F-9G are diagrammatic views of the assembled out-of-plane motion stopper with the moving stage in the negative Z position in accordance with various embodiments of the present disclosure;

FIGS. 9H-9I are diagrammatic views of the assembled out-of-plane motion stopper with the moving stage in the neutral Z position in accordance with various embodiments of the present disclosure;

FIGS. 9J-9K are diagrammatic views of the assembled out-of-plane motion stopper with the moving stage in the positive Z position in accordance with various embodiments of the present disclosure;

FIG. 10A is a diagrammatic view of the integrated in-plane motion limiting snubber and the integrated out-of-plane motion stopper in accordance with various embodiments of the present disclosure;

FIG. 10B is a diagrammatic view of the assembled out-of-plane motion stopper in accordance with various embodiments of the present disclosure;

FIGS. 10C-10D are diagrammatic views of the integrated in-plane motion limiting snubber and the integrated out-of-plane motion stopper in the deployed position with the moving stage in the neutral Z position in accordance with various embodiments of the present disclosure;

FIGS. 10E-10F are diagrammatic views of the integrated in-plane motion limiting snubber and the integrated out-of-plane motion stopper in the deployed position with the moving stage in the positive Z position in accordance with various embodiments of the present disclosure;

FIGS. 10G-10H are diagrammatic views of the integrated out-of-plane motion stopper in the engaged (locked) position and the assembled out-of-plane motion stopper in the engaged (locked) position with the moving stage in the positive Z position in accordance with various embodiments of the present disclosure;

FIG. 11A is a diagrammatic view of a piezoelectric motion stop in accordance with various embodiments of the present disclosure;

FIG. 11B is a diagrammatic view of the piezoelectric motion stop in the engaged (locked) position in accordance with various embodiments of the present disclosure;

FIGS. 12A-12B are diagrammatic views showing assembly of the piezoelectric motion stops into assembly slots of an alignment substrate in accordance with various embodiments of the present disclosure;

FIG. 13A is a diagrammatic view of a MEMS piezoelectric autofocus actuator with assembled piezoelectric motion stops in accordance with various embodiments of the present disclosure;

FIGS. 13B-13C are diagrammatic views of the assembled piezoelectric motion stops in the disengaged (unlocked) position with respect to the moving stage in accordance with various embodiments of the present disclosure;

FIGS. 13D-13E are diagrammatic views of the assembled piezoelectric motion stops in the engaged (locked) position with respect to the moving stage in accordance with various embodiments of the present disclosure;

FIG. 14A is a diagrammatic view of a MEMS piezoelectric autofocus actuator with integrated piezoelectric motion stops in accordance with various embodiments of the present disclosure;

FIG. 14B is a diagrammatic view of the MEMS piezoelectric autofocus actuator with the integrated piezoelectric motion stops experiencing residual stresses in accordance with various embodiments of the present disclosure;

FIG. 15A is a diagrammatic view of the integrated piezoelectric motion stop as fabricated in accordance with various embodiments of the present disclosure;

FIG. 15B is a diagrammatic view of the integrated piezoelectric motion stop experiencing residual stresses in accordance with various embodiments of the present disclosure;

FIGS. 15C-15D are diagrammatic views showing deployment of the integrated piezoelectric motion stop from different angles in accordance with various embodiments of the present disclosure;

FIGS. 15E-15F are diagrammatic views of the integrated piezoelectric motion stop after deployment from different angles, with epoxy dispensed thereon for reinforcement, in accordance with various embodiments of the present disclosure;

FIG. 16A is a closeup view of the integrated piezoelectric motion stop as fabricated in accordance with various embodiments of the present disclosure;

FIG. 16B is a closeup view of the integrated piezoelectric motion stop with residual stresses in accordance with various embodiments of the present disclosure;

FIG. 16C is a closeup view of the integrated piezoelectric motion stop being deployed in accordance with various embodiments of the present disclosure;

FIGS. 16D-16E are closeup views of the deployment lock engaging with the deployment pad during deployment of the integrated piezoelectric motion stop in accordance with various embodiments of the present disclosure;

FIGS. 17A-17C are diagrammatic views showing deployment of the moving stage and the integrated piezoelectric motion stops in accordance with various embodiments of the present disclosure;

FIG. 18A is a diagrammatic view of a MEMS piezoelectric autofocus actuator with integrated piezoelectric motion stops in accordance with various embodiments of the present disclosure;

FIGS. 18B-18C are diagrammatic views of the integrated piezoelectric motion stops in the disengaged (unlocked) position with respect to the moving stage in accordance with various embodiments of the present disclosure; and

FIGS. 18D-18E are diagrammatic views of the integrated piezoelectric motion stops in the engaged (locked) position with respect to the moving stage in accordance with various embodiments of the present disclosure.

### DETAILED DESCRIPTION

### System Overview

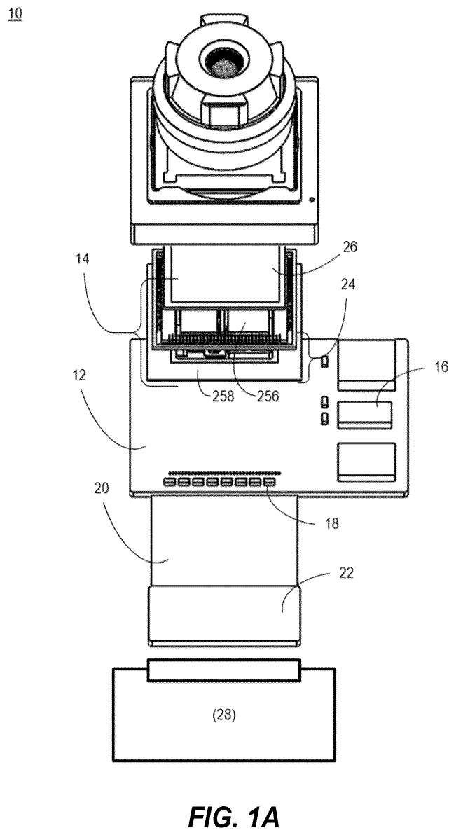

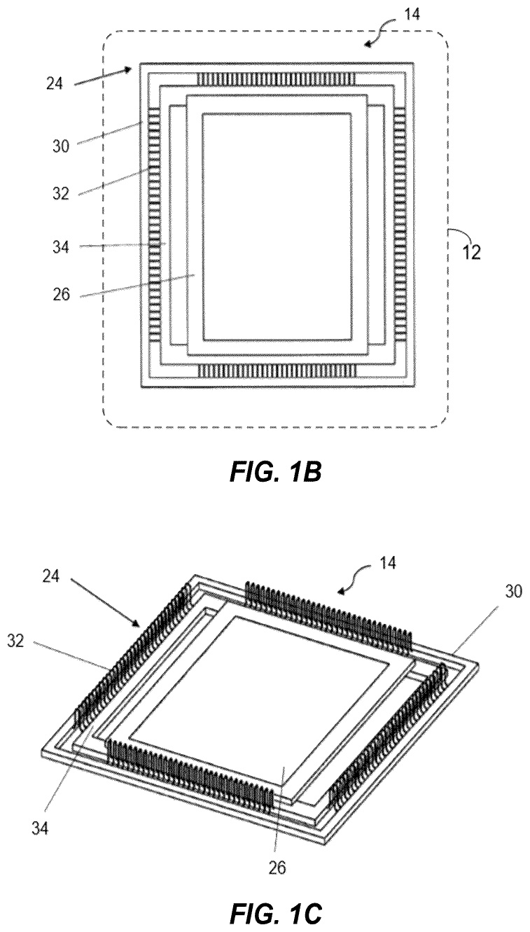

Referring to FIG. 1A, there is shown MEMS camera module 10, in accordance with various aspects of this disclosure. In this example, MEMS camera module 10 is shown to include printed circuit board 12, multi-axis MEMS assembly 14, driver circuits 16, electronic components 18, flexible circuit 20, and electrical connector 22. Multi-axis MEMS assembly 14 may include micro-electrical-mechanical system (MEMS) actuator 24 (configured to provide linear three-axis movement) and optoelectronic device 26 coupled to micro-electrical-mechanical system (MEMS) actuator 24.

As will be discussed below in greater detail, examples of micro-electrical-mechanical system (MEMS) actuator 24 may include but are not limited to an in-plane MEMS actuator, an out-of-plane MEMS actuator, and a combination in-plane/out-of-plane MEMS actuator. For example, and if micro-electrical-mechanical system (MEMS) actuator 24 is an in-plane MEMS actuator, the in-plane MEMS actuator may include an electrostatic comb drive actuation system (as will be discussed below in greater detail). Additionally, if micro-electrical-mechanical system (MEMS) actuator 24 is an out-of-plane MEMS actuator, the out-of-plane MEMS actuator may include a piezoelectric actuation system or electrostatic actuation system. And if micro-electrical-mechanical system (MEMS) actuator 24 is a hybrid in-plane/out-of-plane MEMS actuator, the combination in-plane/out-of-plane MEMS actuator may include an electrostatic comb drive actuation system and a piezoelectric actuation system.

As will be discussed below in greater detail, examples of optoelectronic device 26 may include but are not limited to an image sensor, a holder assembly, an IR filter and/or a lens assembly. Examples of electronic components 18 may include but are not limited to various electronic or semiconductor components and devices. Flexible circuit 20 and/or connector 22 may be configured to electrically couple MEMS camera module 10 to e.g., a smart phone or a digital camera (represented as generic item 28 in FIG. 1A).

In some embodiments, some of the components of MEMS camera module 10 may be joined together using various epoxies/adhesives. For example, an outer frame of micro-electrical-mechanical system (MEMS) actuator 24 may include contact pads that may correspond to similar contact pads on printed circuit board 12.

Referring also to FIG. 1B, there is shown multi-axis MEMS assembly 14, which may include optoelectronic device 26 coupled to micro-electrical-mechanical system (MEMS) actuator 24. As discussed above, examples of micro-electrical-mechanical system (MEMS) actuator 24 may include but are not limited to an in-plane MEMS actuator, an out-of-plane MEMS actuator, and a combination in-plane/out-of-plane MEMS actuator.

When configured to provide in-plane actuation functionality, micro-electrical-mechanical system (MEMS) actuator 24 may include outer frame 30, plurality of electrically conductive flexures 32, MEMS actuation core 34 for attaching a payload (e.g., a device), and attached optoelectronic device 26. Optoelectronic device 26 may be coupled to MEMS actuation core 34 of micro-electrical-mechanical system (MEMS) actuator 24 by epoxy (or various other adhesives/materials and/or bonding methods).

Referring also to FIG. 1C, a plurality of electrically conductive flexures 32 of micro-electrical-mechanical system (MEMS) actuator 24 may be curved upward and buckled to achieve the desired level of flexibility and compression. In the illustrated embodiment, the plurality of electrically conductive flexures 32 may have one end attached to MEMS actuation core 34 (e.g., the moving portion of micro-electrical-mechanical system (MEMS) actuator 24) and the other end attached to outer frame 30 (e.g., the fixed portion of micro-electrical-mechanical system (MEMS) actuator 24).

The plurality of electrically conductive flexures 32 may be conductive wires that may extend above the plane (e.g., an upper surface) of micro-electrical-mechanical system (MEMS) actuator 24 and may electrically couple laterally separated components of micro-electrical-mechanical system (MEMS) actuator 24. For example, the plurality of electrically conductive flexures 32 may provide electrical signals from optoelectronic device 26 and/or MEMS actuation core 34 to outer frame 30 of micro-electrical-mechanical system (MEMS) actuator 24. As discussed above, outer frame 30 of micro-electrical-mechanical system (MEMS) actuator 24 may be affixed to circuit board 12 using epoxy (or various other adhesive materials or devices).

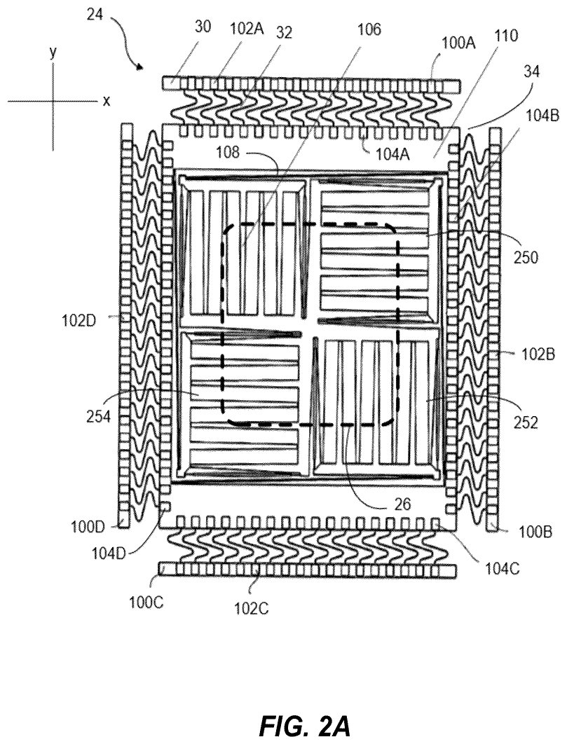

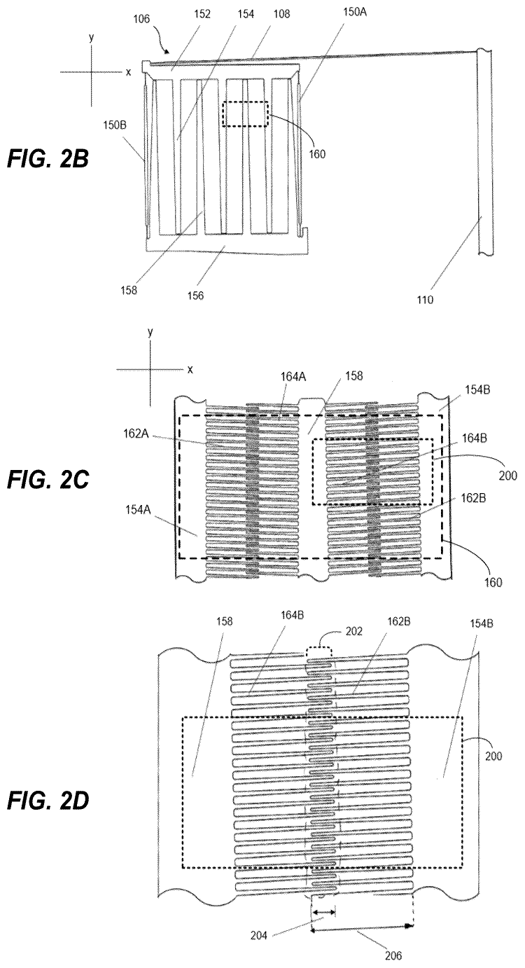

Referring also to FIG. 2A, there is shown a top view of micro-electrical-mechanical system (MEMS) actuator 24 in accordance with various embodiments of the disclosure. Outer frame 30 is shown to include (in this example) four frame assemblies (e.g., frame assembly 100A, frame assembly 100B, frame assembly 100C, frame assembly 100D) that are shown as being spaced apart to allow for additional detail.

Outer frame 30 of micro-electrical-mechanical system (MEMS) actuator 24 may include a plurality of contact pads (e.g., contact pads 102A on frame assembly 100A, contact pads 102B on frame assembly 100B, contact pads 102C on frame assembly 100C, and contact pads 102D on frame assembly 100D), which may be electrically coupled to one end of plurality of electrically conductive flexures 32. The curved shape of electrically conductive flexures 32 is provided for illustrative purposes only and, while illustrating one possible embodiment, other configurations are possible and are considered to be within the scope of this disclosure.

MEMS actuation core 34 may include a plurality of contact pads (e.g., contact pads 104A, contact pads 104B, contact pads 104C, contact pads 104D), which may be electrically coupled to the other end of the plurality of electrically conductive flexures 32. A portion of the contact pads (e.g., contact pads 104A, contact pads 104B, contact pads 104C, contact pads 104D) of MEMS actuation core 34 may be electrically coupled to optoelectronic device 26 by wire bonding, silver paste, or eutectic seal, thus allowing for the electrical coupling of optoelectronic device 26 to outer frame 30.

### Electrostatic Actuation

MEMS actuation core 34 may include one or more comb drive sectors (e.g., comb drive sector 106) that are actuation sectors disposed within micro-electrical-mechanical system (MEMS) actuator 24. The comb drive sectors (e.g., comb drive sector 106) within MEMS actuation core 34 may be disposed in the same plane and may be positioned orthogonal to each other to allow for movement in two axes (e.g., the X-axis and the Y-axis). Accordingly, the in-plane MEMS actuator generally (and MEMS actuation core 34 specifically) may be configured to provide linear X-axis movement and linear Y-axis movement.

While MEMS actuation core 34 is shown to include four comb drive sectors in the particular example shown in FIG. 2A, this is for illustrative purposes only and is not intended to be a limitation of this disclosure, as other configurations are possible. For example, the number of comb drive sectors may be increased or decreased depending upon design criteria.

While the four comb drive sectors are shown to be generally square in shape in the particular example shown in FIG. 2A, this is for illustrative purposes only and is not intended to be a limitation of this disclosure, as other configurations are possible. For example, the shape of the comb drive sectors may be changed to meet various design criteria.

While the comb drive sectors (e.g., comb drive sector 106) within MEMS actuation core 34 are shown to be positioned orthogonal to each other to allow for movement in two axes (e.g., the X-axis and the Y-axis) in the particular example of FIG. 2A, this is for illustrative purposes only and is not intended to be a limitation of this disclosure, as other configurations are possible. For example, the comb drive sectors (e.g., comb drive sector 106) within MEMS actuation core 34 may be positioned parallel to each other to allow for movement in a single axis (e.g., either the X-axis or the Y-axis).

Each comb drive sector (e.g., comb drive sector 106) within MEMS actuation core 34 may include one or more moving portions and one or more fixed portions. As will be discussed below in greater detail, a comb drive sector (e.g., comb drive sector 106) within MEMS actuation core 34 may be coupled, via a cantilever assembly (e.g., cantilever assembly 108), to outer periphery 110 of MEMS actuation core 34 (i.e., the portion of MEMS actuation core 34 that includes contact pads 104A, contact pads 104B, contact pads 104C, contact pads 104D), which is the portion of MEMS actuation core 34 to which optoelectronic device 26 may be coupled, thus effectuating the transfer of movement to optoelectronic device 26.

Referring also to FIG. 2B, there is shown a top view of comb drive sector 106 in accordance with various embodiments of the present disclosure. Each comb drive sector (e.g., comb drive sector 106) may include one or more motion control cantilever assemblies (e.g., motion control cantilever assemblies 150A, 150B) positioned outside of comb drive sector 106, moveable frame 152, moveable spines 154, fixed frame 156, fixed spines 158, and cantilever assembly 108 that is configured to couple moving frame 152 to outer periphery 110 of MEMS actuation core 34. In this particular configuration, motion control cantilever assemblies 150A, 150B may be configured to prevent Y-axis displacement between moving frame 152/moveable spines 154 and fixed frame 156/fixed spines 158.

Comb drive sector 106 may include a movable member including moveable frame 152 and multiple moveable spines 154 that are generally orthogonal to moveable frame 152. Comb drive sector 106 may also include a fixed member including fixed frame 156 and multiple fixed spines 158 that are generally orthogonal to fixed frame 156. Cantilever assembly 108 may be deformable in one direction (e.g., in response to Y-axis deflective loads) and rigid in another direction (e.g., in response to X-axis tension and compression loads), thus allowing for cantilever assembly 108 to absorb motion in the Y-axis but transfer motion in the X-axis.

Referring also to FIG. 2C, there is shown a detail view of portion 160 of comb drive sector 106 of FIG. 2B. Moveable spines 154A, 154B may include a plurality of discrete moveable actuation fingers that are generally orthogonally-attached to moveable spines 154A, 154B. For example, moveable spine 154A is shown to include moveable actuation fingers 162A and moveable spine 154B is shown to include moveable actuation fingers 162B.

Further, fixed spine 158 may include a plurality of discrete fixed actuation fingers that are generally orthogonally-attached to fixed spine 158. For example, fixed spine 158 is shown to include fixed actuation fingers 164A that are configured to mesh and interact with moveable actuation fingers 162A. Further, fixed spine 158 is shown to include fixed actuation fingers 164B that are configured to mesh and interact with moveable actuation fingers 162B.

Accordingly, various numbers of actuation fingers may be associated with (i.e., coupled to) the moveable spines (e.g., moveable spines 154A, 154B) and/or the fixed spines (e.g., fixed spine 158) of comb drive sector 106. As discussed above, each comb drive sector (e.g., comb drive sector 106) may include two motion control cantilever assemblies 150A, 150B separately placed on each side of comb drive sector 106. Each of the two motion control cantilever assemblies 150A, 150B may be configured to couple moveable frame 152 and fixed frame 156, as this configuration enables moveable actuation fingers 162A, 162B to be displaceable in the X-axis with respect to fixed actuation fingers 164A, 164B (respectively) while preventing moveable actuation fingers 162A, 162B from being displaced in the Y-axis and contacting fixed actuation fingers 164A, 164B (respectively).

While actuation fingers 162A, 162B, 164A, 164B (or at least the center axes of actuation fingers 162A, 162B, 164A, 164B) are shown to be generally parallel to one another and generally orthogonal to the respective spines to which they are coupled, this is for illustrative purposes only and is not intended to be a limitation of this disclosure, as other configurations are possible. Further and in some embodiments, actuation fingers 162A, 162B, 164A, 164B may have the same width throughout their length and in other embodiments, actuation fingers 162A, 162B, 164A, 164B may be tapered.

Further and in some embodiments, moveable frame 152 may be displaced in the positive X-axis direction when a voltage potential is applied between actuation fingers 162A and actuation fingers 164A, while moveable frame 152 may be displaced in the negative X-axis direction when a voltage potential is applied between actuation fingers 162B and actuation fingers 164B.

Referring also to FIG. 2D, there is shown a detail view of portion 200 of comb drive sector 106 of FIG. 2C. Fixed spine 158 may be generally parallel to moveable spine 154B, wherein actuation fingers 164B and actuation fingers 162B may overlap within a region (e.g., overlap region 202), wherein the width of the region (e.g., overlap region 202) is typically in the range of 10-50 microns. While overlap region 202 is described as being in the range of 10-50 microns in this particular example, this is for illustrative purposes only and is not intended to be a limitation of this disclosure, as other configurations are possible.

Overlap region 202 may represent the distance 204 where the ends of actuation fingers 162B extends past and overlap the ends of actuation fingers 164B, which are interposed therebetween. In some embodiments, actuation fingers 162B and actuation fingers 164B may be tapered such that their respective tips are narrower than their respective bases (i.e., where they are attached to their spines). Various degrees of taper may be utilized with respect to actuation fingers 162B and actuation fingers 164B. Additionally, the overlap of actuation fingers 162B and actuation fingers 164B provided by overlap region 202 may help ensure that there is sufficient initial actuation force when an electrical voltage potential is applied, so that MEMS actuation core 34 may move gradually and smoothly without any sudden jumps when varying the applied voltage. The height of actuation fingers 162B and actuation fingers 164B may be determined by various aspects of the MEMS fabrication process and various design criteria.

Length 206 of actuation fingers 162B and actuation fingers 164B, the size of overlap region 202, the gaps between adjacent actuation fingers, and actuation finger taper angles that are incorporated into various embodiments may be determined by various design criteria, application considerations, and manufacturability considerations, wherein these measurements may be optimized to achieve the required displacement utilizing the available voltage potential.

As shown in FIG. 2A and as discussed above, MEMS actuation core 34 may include one or more comb drive sectors (e.g., comb drive sector 106), wherein the comb drive sectors (e.g., comb drive sector 106) within MEMS actuation core 34 may be disposed in the same plane and may be positioned orthogonal to each other to allow for movement in two axes (e.g., the X-axis and the Y-axis).

Specifically, and in this particular example, MEMS actuation core 34 is shown to include four comb drive sectors (e.g., comb drive sectors 106, 250, 252, 254). As discussed above, comb drive sector 106 is configured to allow for movement along the X-axis, while preventing movement along the Y-axis. As comb drive sector 252 is similarly configured, comb drive sector 252 may allow for movement along the X-axis, while preventing movement along the Y-axis. Accordingly, if a signal is applied to comb drive sector 106 that provides for positive X-axis movement, while a signal is applied to comb drive sector 252 that provides for negative X-axis movement, actuation core 34 may be displaced in a clockwise direction. Conversely, if a signal is applied to comb drive sector 106 that provides for negative X-axis movement, while a signal is applied to comb drive sector 252 that provides for positive X-axis movement, actuation core 34 may be displaced in a counterclockwise direction.

Further, comb drive sectors 250, 254 are configured (in this example) to be orthogonal to comb drive sectors 106, 252. Accordingly, comb drive sectors 250, 254 may be configured to allow for movement along the Y-axis, while preventing movement along the X-axis. Accordingly, if a signal is applied to comb drive sector 250 that provides for positive Y-axis movement, while a signal is applied to comb drive sector 254 that provides for negative Y-axis movement, actuation core 34 may be displaced in a counterclockwise direction. Conversely, if a signal is applied to comb drive sector 250 that provides for negative Y-axis movement, while a signal is applied to comb drive sector 254 that provides for positive Y-axis movement, actuation core 34 may be displaced in a clockwise direction.

Accordingly, the in-plane MEMS actuator (e.g., micro-electrical-mechanical system (MEMS) actuator 24) generally, and MEMS actuation core 34 more specifically, may be configured to provide rotational (e.g., clockwise or counterclockwise) Z-axis movement of the payload (e.g., optoelectronic device 26).

### Piezoelectric Actuation

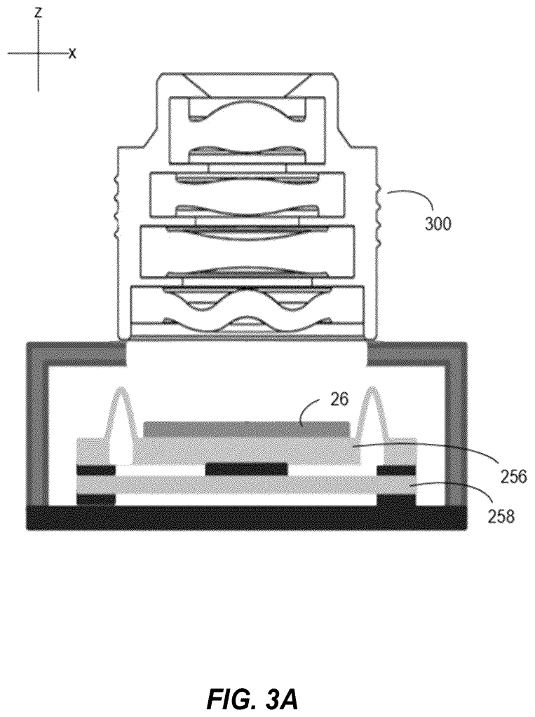

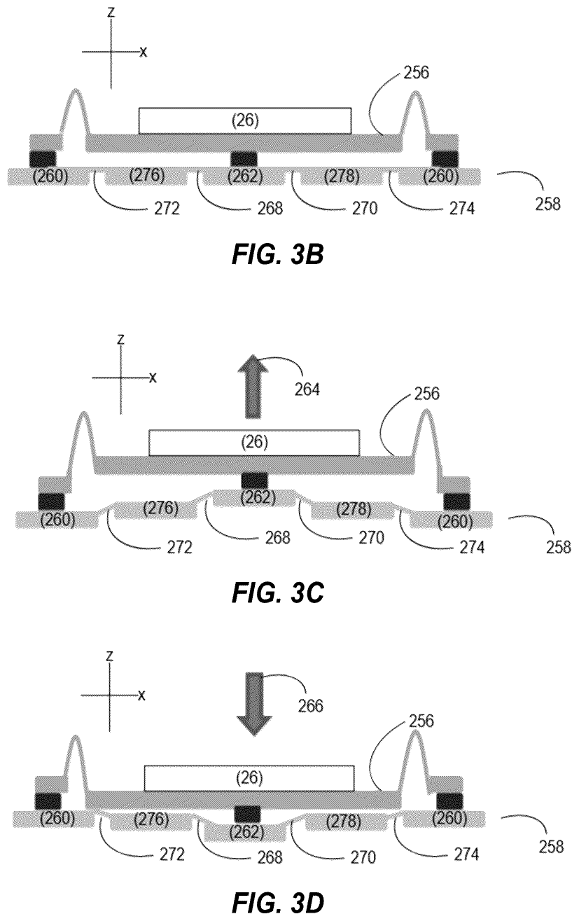

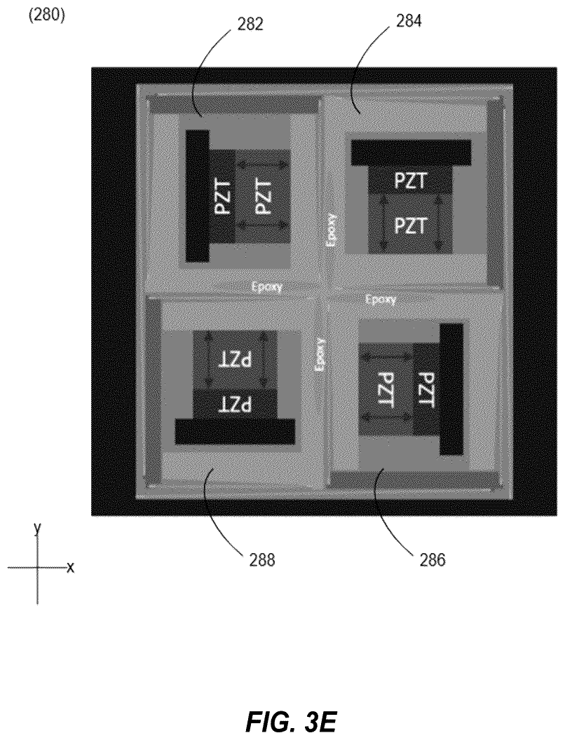

As stated above, examples of micro-electrical-mechanical system (MEMS) actuator 24 may include but are not limited to an in-plane MEMS actuator, an out-of-plane MEMS actuator, and a combination in-plane/out-of-plane MEMS actuator. For example, and referring also to FIG. 3A and FIGS. 3B-3D, micro-electrical-mechanical system (MEMS) actuator 24 is shown to include an in-plane MEMS actuator (e.g., in-plane MEMS actuator 256) and an out-of-plane MEMS actuator (e.g., out-of-plane MEMS actuator 258), wherein FIGS. 2A-2D illustrate one possible embodiment of in-plane MEMS actuator 256. Optoelectronic device 26 may be coupled to in-plane MEMS actuator 256, and in-plane MEMS actuator 256 may be coupled to out-of-plane MEMS actuator 258.

An example of in-plane MEMS actuator 256 may include, but is not limited to, an optical image stabilization (OIS) actuator. As is known in the art, optical image stabilization is a family of techniques that reduce blurring associated with the motion of a camera or other imaging device during exposure. Generally, OIS technology compensates for pan and tilt (angular movement, equivalent to yaw and pitch) of the imaging device, though electronic image stabilization may also compensate for rotation. Optical image stabilization may be used in image-stabilized binoculars, still and video cameras, astronomical telescopes, and smartphones. With still cameras, camera shake may be a particular problem at slow shutter speeds or with long focal length (telephoto or zoom) lenses. With video cameras, camera shake may cause visible frame-to-frame jitter in the recorded video. In astronomy, the problem may be amplified by variations in the atmosphere (which changes the apparent positions of objects over time).

An example of out-of-plane MEMS actuator 258 may include, but is not limited to, an autofocus (AF) actuator. As is known in the art, an autofocus system may use a sensor, a control system, and an actuator to focus on an automatically (or manually) selected area. Autofocus methodologies may be distinguished by their type (e.g., active, passive or hybrid). Autofocus systems may rely on one or more sensors to determine correct focus, wherein some autofocus systems may rely on a single sensor while others may use an array of sensors.

FIG. 3A shows lens assembly 300 with in-plane MEMS actuator 256 and out-of-plane MEMS actuator 258 according to an example embodiment. FIGS. 3B, 3C, and 3D show one possible embodiment of out-of-plane MEMS actuator 258 in various states of activation/excitation, respectively. Referring to FIGS. 3B-3D, out-of-plane MEMS actuator 258 may include frame 260 (a rigid frame assembly which is configured to be stationary) and moveable stage 262, wherein out-of-plane MEMS actuator 258 may be configured to provide linear Z-axis movement. For example, out-of-plane MEMS actuator 258 may include a multi-morph piezoelectric actuator that may be selectively and controllably deformable when an electrical charge is applied, wherein the polarity of the applied electrical charge may vary the direction in which the multi-morph piezoelectric actuator (i.e., out-of-plane MEMS actuator 258) is deformed. For example, FIG. 3B shows out-of-plane MEMS actuator 258 in a natural position without an electrical charge being applied. Further, FIG. 3C shows out-of-plane MEMS actuator 258 in an extended position (i.e., displaced in the direction of arrow 264) with an electrical charge having a first polarity being applied, while FIG. 3D shows out-of-plane MEMS actuator 258 in a retracted position (i.e., displaced in the direction of arrow 266) with an electrical charge having an opposite polarity being applied.

As discussed above, the multi-morph piezoelectric actuator (i.e., out-of-plane MEMS actuator 258) may be deformable by applying an electrical charge. To accomplish such deformability that allows for such linear Z-axis movement, the multi-morph piezoelectric actuator (i.e., out-of-plane MEMS actuator 258) may include a bending piezoelectric actuator, for example.

As discussed above, the multi-morph piezoelectric actuator (i.e., out-of-plane MEMS actuator 258) may include rigid frame assembly 260 (which is configured to be stationary) and moveable stage 262 that may be configured to be affixed to in-plane MEMS actuator 256. As discussed above, optoelectronic device 26 may be coupled to in-plane MEMS actuator 256, and in-plane MEMS actuator 256 may be coupled to out-of-plane MEMS actuator 258. Accordingly, and when out-of-plane MEMS actuator 258 is in an extended position (i.e., displaced in the direction of arrow 264) with an electrical charge having a first polarity being applied (as shown in FIG. 3C), optoelectronic device 26 may be displaced in the positive z-axis direction and towards a lens assembly (e.g., lens assembly 300 of FIG. 3A). Alternatively, and when out-of-plane MEMS actuator 258 is in a retracted position (i.e., displaced in the direction of arrow 266) with an electrical charge having an opposite polarity being applied (as shown in FIG. 3D), optoelectronic device 26 may be displaced in the negative z-axis direction and away from a lens assembly (e.g., lens assembly 300 of FIG. 3A). Accordingly, and by displacing optoelectronic device 26 in the z-axis with respect to a lens assembly (e.g., lens assembly 300 of FIG. 3A), autofocus functionality may be achieved.

The multi-morph piezoelectric actuator (i.e., out-of-plane MEMS actuator 258) may include at least one deformable piezoelectric portion (e.g., deformable piezoelectric portions 268, 270, 272, 274) configured to couple moveable stage 262 to rigid frame assembly 260.

For example, and in one particular embodiment, multi-morph piezoelectric actuator (i.e., out-of-plane MEMS actuator 258) may include a rigid intermediate stage (e.g., rigid intermediate stages 276, 278). A first deformable piezoelectric portion (e.g., deformable piezoelectric portions 268, 270) may be configured to couple rigid intermediate stage (e.g., rigid intermediate stages 276, 278) to moveable stage 262, and a second deformable piezoelectric portion (e.g., deformable piezoelectric portions 272, 274) may be configured to couple the rigid intermediate stage (e.g., rigid intermediate stages 276, 278) to rigid frame assembly 260.

Linear Z-axis (i.e., out-of-plane) movement of moveable stage 262 of out-of-plane MEMS actuator 258 may be generated due to the deformation of the deformable piezoelectric portion (e.g., deformable piezoelectric portions 268, 270, 272, 274), which may be formed of a piezoelectric material (e.g., PZT (lead zirconate titanate), zinc oxide, or other suitable material) that may be configured to deflect in response to an electrical signal. As is known in the art, piezoelectric materials are a special type of ceramic that expands or contracts when an electrical field is applied, thus generating motion and force.

While out-of-plane MEMS actuator 258 is described above as including a single moveable stage (e.g., moveable stage 262) that enables linear movement in the Z-axis, this is for illustrative purposes only and is not intended to be a limitation of this disclosure, as other configurations are possible and are considered to be within the scope of this disclosure. For example, out-of-plane MEMS actuator 258 may be configured to include multiple moveable stages. For example, if deformable piezoelectric portions 272, 274 were configured to be separately controllable, additional degrees of freedom (such as tip and/or tilt) may be achievable. For example and in such a configuration, displacing intermediate stage 276 in an upward direction (i.e., in the direction of arrow 264) while displacing intermediate stage 278 in a downward direction (i.e., in the direction of arrow 266) would result in clockwise rotation of optoelectronic device 26 about the Y-axis, while displacing intermediate stage 276 in a downward direction (i.e., in the direction of arrow 266) while displacing intermediate stage 278 in a upward direction (i.e., in the direction of arrow 264) would result in counterclockwise rotation of optoelectronic device 26 about the Y-axis. Additionally or alternatively, corresponding clockwise and counterclockwise rotation of optoelectronic device 26 about the X-axis may be achieved via additional/alternative intermediate stages.

While FIGS. 3B-3D each show one possible embodiment of an out-of-plane piezoelectric MEMS actuator in various states of activation/excitation, respectively, this is for illustrative purposes only and is not intended to be a limitation of this disclosure, as other configurations are possible and are considered to be within the scope of this disclosure. For example, and as shown in FIG. 3E, an in-plane piezoelectric MEMS actuator 280 may be formed in a fashion similar to that of the above-described in-plane electrostatic MEMS actuators. Accordingly, in-plane piezoelectric MEMS actuator 280 may include a plurality of piezoelectric drive sectors (e.g., piezoelectric drive sectors 282, 284, 286, 288) configured in a similar orthogonal fashion (e.g., piezoelectric drive sectors 282, 286 being configured to enable movement in one axis and piezoelectric drive sectors 284, 288 being configured to enable movement in an orthogonal axis), thus enabling movement in the X-axis and the Y-axis, and rotation about the Z-axis, for moving the payload (e.g., optoelectronic device 26).

### MEMS Image Sensor Assembly

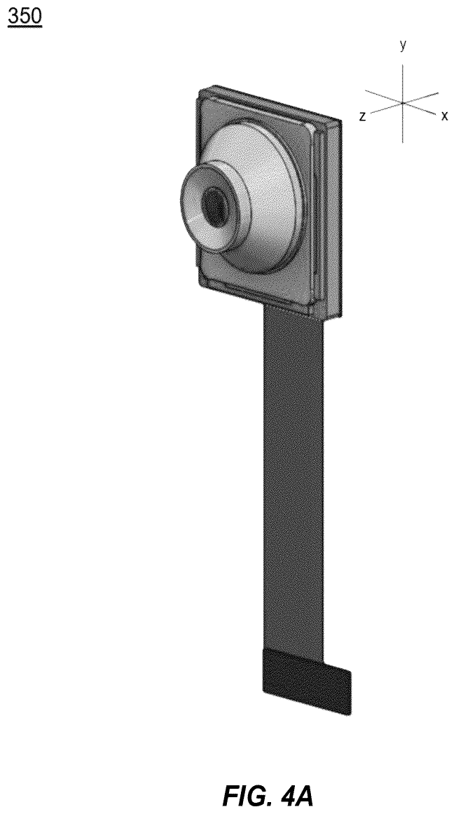

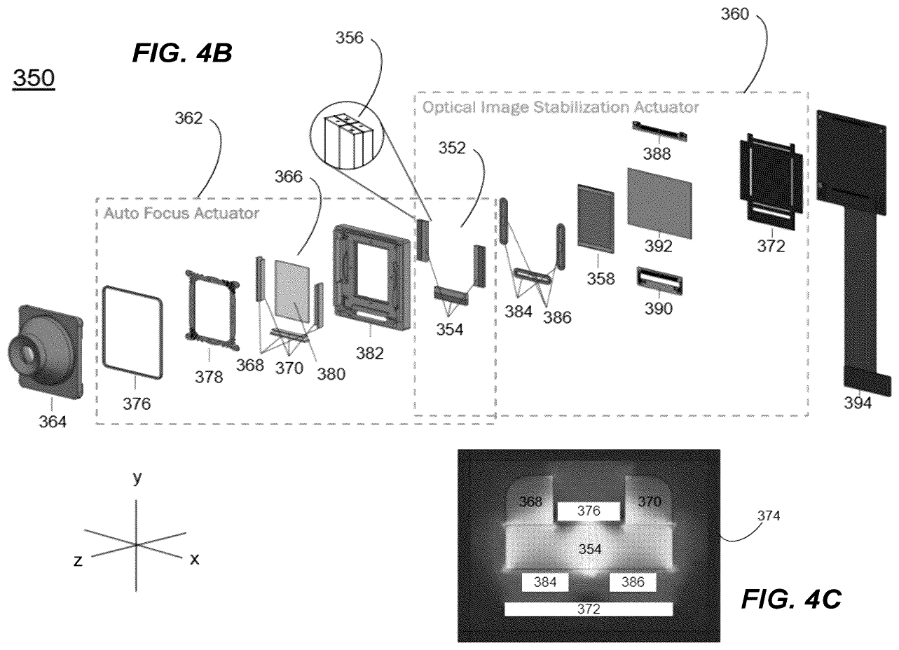

Referring also to FIG. 4A and FIG. 4B, there is shown a MEMS image sensor assembly (e.g., MEMS image sensor assembly 350). MEMS image sensor assembly 350 may include a common magnet assembly (e.g., common magnet assembly 352). In this particular example, common magnet assembly 352 is referred to as being “common” because it is utilized to effectuate both in-plane and out-of-plane movement.

In the context of MEMS devices (e.g., MEMS image sensor assembly 350), “in-plane” and “out-of-plane” movements refer to different directions of motion within the device (e.g., MEMS image sensor assembly 350). These terms describe how components or structures within the MEMS device (e.g., MEMS image sensor assembly 350) can move relative to the device's substrate or plane. The following is an explanation of the differences between in-plane movement and out-of-plane movement:
1. In-Plane Movement:
   Definition: In-plane movement refers to motion that occurs within the same plane or surface as the device's substrate. It is motion along the X and Y axes, or lateral motion.
   Example: If you have a MEMS accelerometer on a chip, in-plane movement might involve the tiny sensing mass moving horizontally (left-right or up-down) within the same plane as the chip's surface to detect acceleration.
2. Out-of-Plane Movement:
   Definition: Out-of-plane movement, also known as vertical or Z-axis movement, refers to motion that occurs perpendicular to the device's substrate or plane. It is motion along the Z-axis, which is often considered the direction coming out of the plane of the chip.
   Example: In a MEMS micro-mirror device used in optical applications, out-of-plane movement involves the mirror tilting or rotating vertically away from or towards the substrate to redirect light beams.

To illustrate the difference, imagine a MEMS device (e.g., MEMS image sensor assembly 350) on a flat chip, such as a tiny mechanical component. If this component moves side to side or up and down on the same plane as the chip's surface, that is considered in-plane movement. If this component moves away from or towards the surface, perpendicular to the chip's plane, that is considered out-of-plane movement. Both types of movement have their applications in MEMS devices, and they can be used for various purposes, such as sensing, actuation, or manipulation of physical phenomena, for example. MEMS technology enables precise control of these movements, making it valuable in a wide range of industries, including electronics, sensors, medical devices, and more.

Referring to FIG. 4B, the common magnet assembly (e.g., common magnet assembly 352) may include a plurality of magnet assemblies (e.g., plurality of magnet assemblies 354). Examples of the plurality of magnet assemblies (e.g., plurality of magnet assemblies 354) may include a plurality of permanent magnet assemblies.

A permanent magnet is a type of magnet that retains its magnetic properties and generates a magnetic field without the need for an external power source, such as electricity. Unlike electromagnets, which require an electric current to create a magnetic field, permanent magnets are made from materials that have inherent magnetic properties.

Key characteristics of permanent magnets include:
Stability: Permanent magnets maintain their magnetic properties over an extended period, provided they are not subjected to conditions that could weaken or demagnetize them.
Magnetic Field: They generate a magnetic field that has north and south poles, and they exert attractive or repulsive forces on other magnetic materials or objects, depending on their orientation.
Materials: Permanent magnets are typically made from specific materials known as ferromagnetic materials, which include substances like iron, nickel, cobalt, and certain alloys.
Applications: Permanent magnets are used in various applications, such as electric motors, generators, magnetic locks, compasses, speakers, MRI machines, magnetic sensors, and more.
Shapes and Types: Permanent magnets can come in various shapes and forms, including bar magnets, horseshoe magnets, ring magnets, and more. They can also be categorized into different types, such as neodymium magnets (strongest commercially available magnets), ferrite magnets (ceramic magnets), and alnico magnets (aluminum, nickel, and cobalt alloys).
Magnetization: The process of creating a permanent magnet involves exposing the material to a strong external magnetic field or striking it while in a magnetic field. This aligns the magnetic domains within the material, creating a permanent magnet.
Demagnetization: While permanent magnets are relatively stable, they can be demagnetized or weakened if exposed to extreme heat, physical shock, or strong opposing magnetic fields.

Permanent magnets are integral to many technologies and devices that rely on magnetic interactions, and they play a crucial role in the functioning of various everyday items and industrial equipment. Their ability to generate a constant magnetic field without the need for an external power source makes them highly valuable in a wide range of applications.

The plurality of magnet assemblies (e.g., the plurality of magnet assemblies 354) may include a plurality of laminated magnet assemblies. For example, each of the plurality of magnet assemblies (e.g., plurality of magnet assemblies 354) may actually include multiple magnets that are positioned proximate and/or laminated to each other to form a plurality of magnet assemblies that form grid of magnetic poles 356.

MEMS image sensor assembly 350 may include an image sensor subassembly (e.g., image sensor subassembly 358). An example of an image sensor subassembly (e.g., image sensor subassembly 358) may include an optoelectronic device.

An image sensor subassembly (e.g., image sensor subassembly 358) refers to a component or module within a digital imaging system, such as a camera or a scanner, that includes one or more image sensors and associated components. Image sensor subassemblies are critical to the functioning of these devices as they are responsible for capturing and converting light or optical information into digital signals.

Some key components typically found in an image sensor subassembly include:
Image Sensor: The core component is the image sensor itself. This can be a CCD (Charge-Coupled Device) sensor, CMOS (Complementary Metal-Oxide-Semiconductor) sensor, or other specialized sensor types. The image sensor captures incoming light and converts it into an electrical signal.
Filter and Color Processing: In many image sensor subassemblies, filters are used to control the wavelengths of light that reach the sensor. This can include color filters for capturing RGB (Red, Green, Blue) information or specialized filters for specific applications, such as infrared or ultraviolet imaging.
Signal Processing Electronics: The subassembly may include electronics for amplifying, processing, and digitizing the electrical signals generated by the image sensor. This is essential for converting analog light information into digital image data.
Microcontrollers or Processors: In more advanced image sensor subassemblies, there may be microcontrollers or processors that handle various tasks, such as image signal processing, autofocus, exposure control, and optical image stabilization (OIS).
Mounting and Housing: These components are used to securely hold the image sensor and other elements in place within the device's overall structure.
Connectors: Image sensor subassemblies typically have connectors that allow them to interface with the rest of the imaging system or device, including data transfer and power connections.

Image sensor subassemblies (e.g., image sensor subassembly 358) can vary significantly in complexity and features, depending on the intended use and the sophistication of the imaging system. For instance, a smartphone camera module contains a relatively compact image sensor subassembly, while a high-end digital camera may have a more intricate and modular subassembly with interchangeable lenses.

MEMS image sensor assembly 350 may include an in-plane actuation subassembly (e.g., in-plane actuation subassembly 360) that utilizes the common magnet assembly (e.g., common magnet assembly 352) to effectuate in-plane movement of the image sensor subassembly (e.g., image sensor subassembly 358) and/or a lens assembly (e.g., lens assembly 364 to be discussed below in greater detail).

The in-plane actuation subassembly (e.g., in-plane actuation subassembly 360) may be an optical image stabilization (OIS) subassembly. An optical image stabilization (OIS) subassembly (e.g., in-plane actuation subassembly 360) is a key component of the camera system that is designed to reduce the blurriness and shakiness in photos and videos caused by hand tremors or movements when taking pictures or recording videos with a mobile phone (e.g., represented as generic item 28 in FIG. 1A). Optical image stabilization technology helps improve the overall image and video quality by compensating for these unintentional movements.

The primary components and features of an optical image stabilization (OIS) subassembly in a cellphone (represented as generic item 28) include:
Gyroscopic Sensors or Accelerometers: These sensors are integrated into the phone (represented as generic item 28) to detect any angular or linear movements or vibrations of the device during photography or video recording.
Actuators or Motors: OIS assemblies include small, precise motors or actuators that physically move the camera lens or image sensor to counteract the detected motion.
Feedback Loop: OIS systems operate within a feedback loop that continuously receives data from the sensors, evaluates the camera's movement, and calculates the necessary adjustments to stabilize the image or video.
Lens or Sensor Movement: In response to the sensor data, the OIS assembly shifts the camera lens or image sensor slightly to compensate for the detected motion. These movements can occur in multiple directions (typically pitch and yaw) to address various types of motion.
Control Circuitry and Algorithms: The cellphone's electronics and control algorithms are responsible for processing data from the sensors and orchestrating the adjustments required to maintain image stability.
Real-time Correction: OIS adjustments occur in real-time as you capture images or record videos, ensuring that the final output is as steady and sharp as possible.

The main benefits of optical image stabilization in a cellphone camera include:
Reduced Blurriness: OIS significantly reduces the blur in photos and videos, leading to sharper and clearer results.
Enhanced Low-Light Performance: OIS allows for longer exposure times in low-light conditions, resulting in better image quality without blur.
Smoother Video Recording: OIS is particularly useful for recording smooth and steady videos, as it minimizes the shakiness often associated with handheld recording.
Improved Overall Image Quality: Whether taking photos or recording videos, OIS contributes to better image quality by compensating for motion-induced imperfections.

The presence and effectiveness of optical image stabilization can vary among different cellphone models. High-end and flagship smartphones typically feature more advanced OIS systems, while budget or mid-range phones may have simpler implementations. OIS has become a standard feature in many modern smartphones, enhancing the overall photography and videography experience for users.

MEMS image sensor assembly 350 may include an out-of-plane actuation subassembly (e.g., out-of-plane actuation subassembly 362) that utilizes the common magnet assembly (e.g., common magnet assembly 352) to effectuate out-of-plane movement of the image sensor subassembly (e.g., image sensor subassembly 362) and/or the lens assembly (e.g., lens assembly 364 to be discussed below in greater detail).

The out-of-plane actuation subassembly (e.g., out-of-plane actuation subassembly 362) may be an autofocus (AF) subassembly. An autofocus (AF) subassembly (e.g., out-of-plane actuation subassembly 362) refers to the components and mechanisms responsible for automatically adjusting the focus of the phone's camera to capture sharp and clear images or videos. Most modern smartphones (represented as generic item 28) are equipped with sophisticated autofocus systems to make it easier for users to take high-quality photos and videos without the need for manual focus adjustments.

An autofocus (AF) assembly in a cell phone (represented as generic item 28) typically includes:
Focus Motor: Smartphones use small electric motors or actuators that can physically move the camera lens or the image sensor to achieve focus. Depending on the phone's design, this motor may be voice coil autofocus (VCM) or piezoelectric-based, among others.
Image Sensor: In many smartphones, the entire image sensor or a specific part of it can be moved to adjust the focus. This is known as sensor-based autofocus or sensor-shift autofocus.
Control Electronics: The phone's processor and control algorithms play a crucial role in determining when and how to adjust the focus. These algorithms may analyze image data to assess focus accuracy.
Focus Sensors: Some smartphones use dedicated sensors, such as phase-detection or laser autofocus sensors, to measure the focus accuracy. These sensors help the system quickly and accurately determine the correct focus point, especially in challenging lighting conditions.
Focus Modes: Cell phones (represented as generic item 28) often provide various focus modes, such as single-shot autofocus (focuses once and locks the focus until a new command is given), continuous autofocus (keeps adjusting focus for moving subjects), or even manual focus control through the touchscreen interface.
Feedback Mechanism: A feedback loop continuously evaluates the image's focus quality and makes fine adjustments as needed until the subject is sharp.
Software Enhancements: Smartphone cameras also use software enhancements, such as face detection, object tracking, and scene recognition, to optimize focus for different shooting scenarios.

The autofocus (AF) assembly in a cell phone (represented as generic item 28) is essential for capturing high-quality photos and videos effortlessly. It allows users to focus on framing and composition without the need to manually adjust focus settings. The sophistication of the autofocus system can vary between smartphone models, with flagship phones often featuring more advanced and faster autofocus mechanisms, which is particularly useful for capturing fast-moving subjects or shooting in challenging lighting conditions.

As referenced above, MEMS image sensor assembly 350 may include a lens assembly (e.g., lens assembly 364) positioned proximate the image sensor subassembly (e.g., image sensor subassembly 358).

A lens assembly (e.g., lens assembly 364) in a cell phone, often referred to as a camera lens module or camera module, is a key component of the smartphone's camera system. It plays a crucial role in capturing photos and videos by focusing light onto the image sensor (e.g., image sensor subassembly 358), thereby creating a clear and sharp image. The lens assembly (e.g., lens assembly 364) is responsible for controlling various aspects of the photographic process, including focus, aperture, and image quality.

The main components and functions of a lens assembly in a cell phone typically include:
Lens Elements: The lens assembly typically includes multiple lens elements made of glass or specialized optical materials. These lens elements are arranged to bend and direct incoming light onto the image sensor. The combination and arrangement of these elements affect the camera's field of view, depth of field, and image quality.
Aperture Mechanism: Many cell phone camera lens assemblies incorporate an adjustable aperture mechanism. The aperture controls the amount of light that enters the camera, which in turn affects exposure and depth of field. A wider aperture (lower f-number) allows more light in and is useful for low-light conditions, while a narrower aperture (higher f-number) provides greater depth of field.
Focus Mechanism: The lens assembly contains components for focusing, either manually or automatically. Autofocus systems use tiny motors to adjust the position of the lens elements or the entire lens assembly to achieve precise focus on the subject. An image sensor can also be moved for focusing in certain instances. Some lens assemblies also support optical image stabilization (OIS) to reduce blurriness caused by hand tremors or motion.
Image Quality Enhancements: Many lens assemblies include coatings or technologies to improve image quality, such as anti-reflective coatings to reduce lens flare and ghosting, as well as optical image stabilization (OIS) to reduce image blur.
Protective Elements: The lens assembly often includes protective elements like a scratch-resistant glass cover or protective coatings to safeguard the lens from damage and debris.
Mounting and Integration: The lens assembly is securely mounted within the cell phone's camera housing, ensuring that it remains stable and aligned for consistent image quality. It is also integrated with the camera's sensor, image processing electronics, and software.
Connectors and Wiring: There are connectors and wiring within the lens assembly to establish communication with the phone's image processing unit and to transmit image data.

The lens assembly in a cell phone camera is a critical component that significantly impacts the overall photographic capabilities of the device. Manufacturers invest in the design and quality of these assemblies to provide users with features like high-resolution photography, advanced focus capabilities, low-light performance, and various shooting modes. Different phone models may have different lens assembly configurations, and advancements in this technology continue to drive improvements in mobile photography.

MEMS image sensor assembly 350 may include a flux redirection assembly (e.g., flux redirection assembly 366) positioned proximate the common magnet assembly (e.g., common magnet assembly 352). The flux redirection assembly (e.g., flux redirection assembly 366) may include: one or more steel subassemblies (e.g., steel subassemblies 368, 370, 372) configured to redirect the flux of the common magnet assembly (e.g., common magnet assembly 352), as shown in magnetic flux graph 374 of FIG. 4C. FIG. 4C is a cross-sectional view of an electromagnetic actuator assembled as part of the MEMS image sensor assembly 350 of FIGS. 4A-4B, with the magnetic flex graph 374 imposed over the cross-section.

Also shown in FIG. 4B, various additional components of MEMS image sensor assembly 350 may include: autofocus coil 376 (which may be configured to interact with common magnet assembly 352 and control out-of-plane movement of out-of-plane actuation subassembly 362); autofocus spring 378 (for biasing out-of-plane actuation subassembly 362 into a default position); IR glass filter 380 (for filtering infrared light passing through lens assembly 364); IR & magnet holder 382 (for positioning lens assembly 364 & steel subassemblies 368, 370); optical image stabilization coils 384, 386 (which may be configured to interact with common magnet assembly 352 and control in-plane movement of in-plane actuation subassembly 360); top MEMS spring 388 (for biasing in-plane actuation subassembly 360 into a default position); bottom MEMS spring 390 (for biasing in-plane actuation subassembly 360 into a default position); OIS metal plate 392 (for mounting various portions of in-plane actuation subassembly 360); and RFPCB 394 (for coupling MEMS image sensor assembly 350 to a printed circuit board).

As discussed above, autofocus coil 376 may be configured to interact with common magnet assembly 352 and control out-of-plane movement of out-of-plane actuation subassembly 362, wherein optical image stabilization coils 384, 386 may be configured to interact with common magnet assembly 352 and control in-plane movement of in-plane actuation subassembly 360.

Specifically, and with respect to autofocus coil 376, by controlling the level of current passing through autofocus coil 376, a magnetic field may be generated that interacts with plurality of magnet assemblies 354 to generate attraction or repulsion forces along the Z-axis of MEMS image sensor assembly 350, thus resulting in Z-axis displacement and the effectuation of such autofocus functionality. For example, the magnetic field generated may displace the lens assembly (e.g., lens assembly 364) and/or the image sensor subassembly (e.g., image sensor subassembly 358) along the Z-axis to effectuate such autofocus functionality.

Accordingly, and with respect to autofocus coil 376, passing a current (I) through autofocus coil 376 in a first direction may result in negative Z-axis displacement, wherein the quantity of such negative Z-axis displacement may be controlled by adjusting the level of current passing through autofocus coil 376 in the first direction. Conversely, passing a current (I) through autofocus coil 376 in a second (i.e., opposite) direction may result in positive Z-axis displacement, wherein the quantity of such positive Z-axis displacement may be controlled by adjusting the level of current passing through autofocus coil 376 in the second (i.e., opposite) direction.

Further, and with respect to optical image stabilization coils 384, 386, by controlling the level of current passing through one or more of optical image stabilization coils 384, 386, a magnetic field may be generated that interacts with plurality of magnet assemblies 354 to generate attraction or repulsion forces along the X-axis and/or Y-axis of MEMS image sensor assembly 350, thus resulting in X-axis and/or Y-axis displacement and the effectuation of such optical image stabilization (OIS) functionality. For example, the magnetic field generated may displace the lens assembly (e.g., lens assembly 364) and/or the image sensor subassembly (e.g., image sensor subassembly 358) along the X-axis and/or Y-axis to effectuate such OIS functionality.

Accordingly, and with respect to optical image stabilization coils 384, 386, passing a current (I) through one or more of image stabilization coils 384, 386 in a first direction may result in negative X-axis and/or Y-axis displacement, wherein the quantity of such negative X-axis and/or Y-axis displacement may be controlled by adjusting the level of current passing through one or more of image stabilization coils 384, 386 in the first direction. Conversely, passing a current (I) through one or more of image stabilization coils 384, 386 in a second (i.e., opposite) direction may result in positive X-axis and/or Y-axis displacement, wherein the quantity of such positive X-axis and/or Y-axis displacement may be controlled by adjusting the level of current passing through one or more of image stabilization coils 384, 386 in the second (i.e., opposite) direction.

As discussed above, MEMS image sensor assembly 350 may include a flux redirection assembly (e.g., flux redirection assembly 366) positioned proximate the common magnet assembly (e.g., common magnet assembly 352). The flux redirection assembly (e.g., flux redirection assembly 366) may include one or more steel subassemblies (e.g., steel subassemblies 368, 370, 372) configured to redirect the flux (e.g., of common magnet assembly 352, of image stabilization coils 384, 386 and/or of autofocus coil 376), as shown in magnetic flux graph 374 of FIG. 4C.

While MEMS image sensor assembly 350 is shown to include a single autofocus spring (e.g., autofocus spring 378 for biasing out-of-plane actuation subassembly 362 into a default position), this is for illustrative purposes only and is not intended to be a limitation of this disclosure, as other configurations are possible and are considered to be within the scope of this disclosure. For example, MEMS image sensor assembly 350 may be configured to include multiple autofocus springs (e.g., a top autofocus spring and a bottom autofocus spring).

As discussed above, the common magnet assembly (e.g., common magnet assembly 352) may include a plurality of magnet assemblies (e.g., plurality of magnet assemblies 354). While plurality of magnet assemblies 354 is shown in FIG. 4B to include three magnet assemblies, this is for illustrative purposes only and is not intended to be a limitation of this disclosure, as other configurations are possible and are considered to be within the scope of this disclosure. For example, additional magnet assemblies (e.g., a fourth magnet assembly) may be included within common magnet assembly 352 to assist with Z-axis movement. When such additional magnet assemblies (e.g., a fourth magnet assembly) are included within common magnet assembly 352, the flux redirection assembly (e.g., flux redirection assembly 366) may include: additional steel subassemblies configured to redirect the flux (e.g., of common magnet assembly 352), of image stabilization coils 384, 386 and/or of autofocus coil 376), as shown in magnetic flux graph 374 of FIG. 4C.

### MEMS Flexures

As discussed above with reference to FIGS. 1B-1C and FIG. 2A, when configured to provide in-plane actuation functionality, a micro-electrical-mechanical system (MEMS) actuator 24 may include outer frame 30, a plurality of electrically conductive flexures 32, a MEMS actuation core 34 for attaching a payload (e.g., a device), and an attached optoelectronic device 26. The plurality of electrically conductive flexures 32 of micro-electrical-mechanical system (MEMS) actuator 24 may be curved upward and buckled to achieve the desired level of flexibility and compression. In the illustrated embodiment, the plurality of electrically conductive flexures 32 may have one end attached to MEMS actuation core 34 (e.g., the moving portion of micro-electrical-mechanical system (MEMS) actuator 24) and the other end attached to outer frame 30 (e.g., the fixed portion of micro-electrical-mechanical system (MEMS) actuator 24). The plurality of electrically conductive flexures 32 may be conductive wires that may extend above the plane (e.g., an upper surface) of micro-electrical-mechanical system (MEMS) actuator 24, and may electrically couple laterally separated components of micro-electrical-mechanical system (MEMS) actuator 24. For example, the plurality of electrically conductive flexures 32 may provide electrical signals from optoelectronic device 26 and/or MEMS actuation core 34 to outer frame 30 of micro-electrical-mechanical system (MEMS) actuator 24.

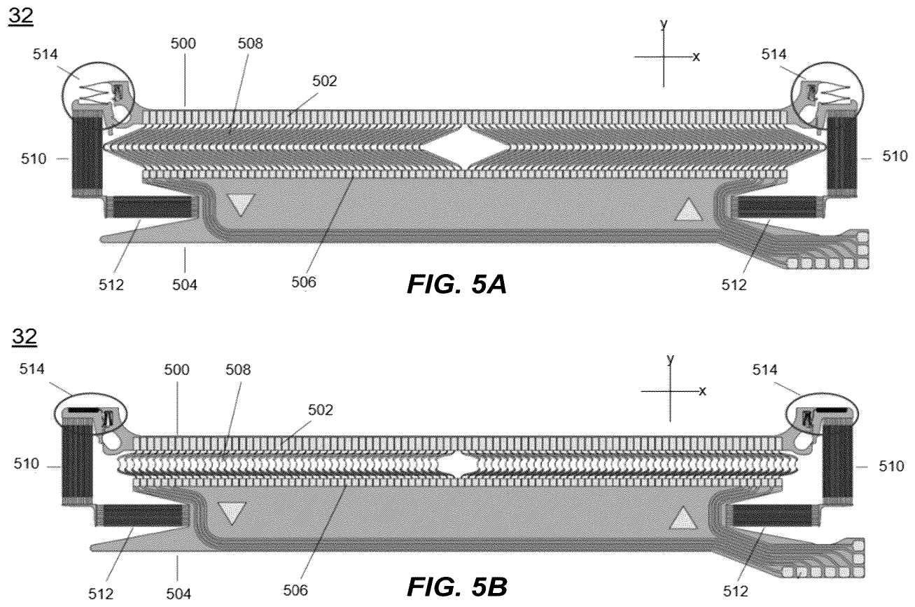

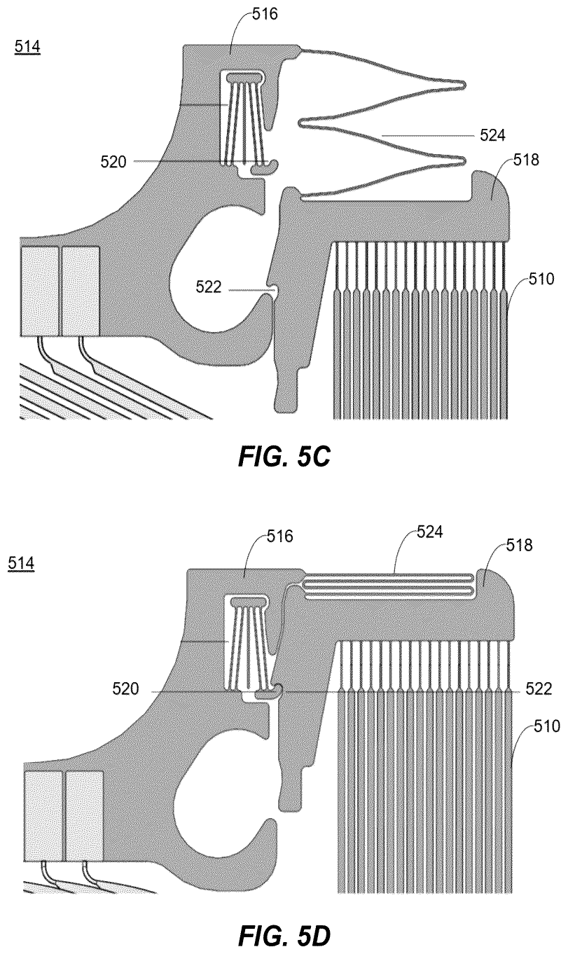

Referring also to FIG. 5A and FIG. 5B, an electrically-conductive, MEMS flexure assembly (e.g., electrically-conductive, MEMS flexure assembly 32) may include: a first MEMS subportion (e.g., first MEMS subportion 500) including a first plurality of electrically-conductive pads (e.g., a first plurality of electrically-conductive pads 502); and a second MEMS subportion (e.g., a second MEMS subportion 504) including a second plurality of electrically-conductive pads (e.g., a second plurality of electrically-conductive pads 506).

The plurality of electrically-conductive pads (e.g., the first plurality of electrically-conductive pads 502 and/or the second plurality of electrically-conductive pads 506) may include a plurality of electrically-conductive wire-bond pads, to which conductors and/or components may be electrically coupled, for example.

Electrically conductive wire-bond pads are areas on an electronic component or semiconductor device specifically designed for wire bonding. Wire bonding is a technique used in the semiconductor industry to create interconnections between an integrated circuit or chip and other components. The wire-bond pads are usually made of conductive materials like aluminum, copper, or gold and are positioned in a specific layout on the chip. They serve as connection points for thin wires, allowing electrical signals to be transmitted between the chip and other parts of the electronic circuit or other chips. Wire bonding typically involves using a fine wire made of a conductive material to create the electrical connection between the wire-bond pads on the chip and the package or substrate. This connection is often made through the process of thermosonic bonding or ultrasonic bonding, where heat, pressure, and ultrasonic energy are applied to attach the wire to the pads, establishing the electrical connection. The wire-bond pads' design and material composition play a crucial role in ensuring reliable electrical connections, signal integrity, and the overall performance of the electronic device or semiconductor component. Different types of wire-bond pads might be used based on the requirements of the specific application, the materials involved, and the manufacturing processes employed.

The plurality of electrically-conductive pads (e.g., the first plurality of electrically-conductive pads 502 and/or the second plurality of electrically-conductive pads 506) may include a plurality of electrically-conductive solder pads, to which conductors and/or components may be electrically coupled, for example.

Electrically conductive solder pads refer to specific areas or points on a substrate or electronic component designed for the application of soldering. These pads are meant to establish a conductive pathway for electrical connections, allowing components to be joined together. Solder pads are typically made from conductive materials such as copper, silver, or other metals that facilitate the soldering process. The solder, usually a metal alloy with a low melting point, is applied to these pads to create a strong mechanical and electrical bond between components. When heated, the solder melts and adheres to the conductive pads, forming a secure electrical connection upon cooling. The electrical conductivity of the pads is crucial to ensure a reliable and low-resistance pathway for the flow of electrical current. Properly designed and manufactured solder pads are essential for a solid and durable solder joint, preventing electrical discontinuities, and ensuring good signal integrity. These pads are fundamental in various electronic manufacturing processes, especially in surface-mount technology (SMT), where components are soldered directly onto the surface of a printed circuit board (PCB). Solder pads can vary in size, shape, and arrangement based on the specific requirements of the circuit design, component size, and the soldering method used in the manufacturing process.

As shown in FIGS. 5A-5B, the electrically-conductive, MEMS flexure assembly (e.g., electrically-conductive, MEMS flexure assembly 32) may include a plurality of MEMS electrically-conductive flexures (e.g., a plurality of MEMS electrically-conductive flexures 508) electrically coupling the first plurality of electrically-conductive pads (e.g., the first plurality of electrically-conductive pads 502) on the first MEMS subportion (e.g., first MEMS subportion 500) and the second plurality of electrically-conductive pads (e.g., the second plurality of electrically-conductive pads 506) on the second MEMS subportion (e.g., second MEMS subportion 504).

In MEMS devices (e.g., micro-electrical-mechanical system (MEMS) actuator 24), electrically conductive flexures (e.g., electrically-conductive, MEMS flexure assembly 32) are structural elements that provide both mechanical flexibility and electrical conductivity within the device. MEMS devices often involve tiny mechanical components and electrical circuits integrated onto a single substrate. Electrically conductive flexures play a critical role in these systems by allowing controlled movement or flexing of certain parts while maintaining electrical connectivity. These flexures can be engineered to bend or move in response to mechanical or electrical stimuli, and they can simultaneously carry electrical signals or power. They can be designed in various ways, such as serpentine structures, cantilever beams, or other flexible configurations.

Applications of electrically conductive flexures in MEMS devices include:
Sensors and Actuators: Flexures can be a part of sensors or actuators within MEMS devices. For instance, in accelerometers, the flexures might be used to detect changes in acceleration. In micro-actuators, they could facilitate movement or mechanical manipulation.
Electrical Connectivity: These flexures maintain electrical connectivity across moving parts or elements within the MEMS device. For instance, in a device where parts need to move or rotate while maintaining electrical connections, these flexures enable such movement without losing conductivity.
Signal Transmission: These flexures can also be part of transmission lines or conductive pathways that allow signals or power to pass through moving components without interruption.

The design and material used for these flexures are crucial to ensure the desired mechanical flexibility while maintaining electrical conductivity. They are often manufactured using conductive materials like metals (such as gold, copper, or aluminum) or conductive polymers, carefully structured to combine the needed mechanical and electrical properties. Their implementation is integral to the functionality and reliability of MEMS devices.

The electrically-conductive, MEMS flexure assembly (e.g., electrically-conductive, MEMS flexure assembly 32) may be configured to allow deformation of the plurality of MEMS electrically-conductive flexures (e.g., the plurality of MEMS electrically-conductive flexures 508) in two axes.

For example, the electrically-conductive, MEMS flexure assembly (e.g., electrically-conductive, MEMS flexure assembly 32) may include an X-axis displacement assembly (e.g., X-axis displacement assembly 510) configured to allow deformation of the plurality of MEMS electrically-conductive flexures (e.g., the plurality of MEMS electrically-conductive flexures 508) in the X-axis, thus allowing movement of the first MEMS subportion (e.g., first MEMS subportion 500) with respect to the second MEMS subportion (e.g., second MEMS subportion 504) along the X-axis.

Further, the electrically-conductive, MEMS flexure assembly (e.g., electrically-conductive, MEMS flexure assembly 32) may include a Y-axis displacement assembly (e.g., Y-axis displacement assembly 512) configured to allow deformation of the plurality of MEMS electrically-conductive flexures (e.g., plurality of MEMS electrically-conductive flexures 508) in the Y-axis, thus allowing movement of the first MEMS subportion (e.g., first MEMS subportion 500) with respect to the second MEMS subportion (e.g., second MEMS subportion 504) along the Y-axis.

As also shown in FIGS. 5A-5B, the electrically-conductive, MEMS flexure assembly (e.g., electrically-conductive, MEMS flexure assembly 32) may include a latching assembly (e.g., latching assembly 514) configured to couple the first MEMS subportion (e.g., first MEMS subportion 500) and the second MEMS subportion (e.g., second MEMS subportion 504) in a latched configuration (as shown in FIG. 5B and FIG. 5D).

Referring to FIG. 5C and FIG. 5D, the latching assembly (e.g., latching assembly 514) may include: a first latching portion (e.g., first latching portion 516); and a second latching portion (e.g., second latching portion 518). For example, the first latching portion (e.g., first latching portion 516) of the latching assembly (e.g., latching assembly 514) may include a biased latch bolt (e.g., biased latch bolt 520), wherein the second latching portion (e.g., second latching portion 518) of the latching assembly (e.g., latching assembly 514) may include a bolt recess (e.g., bolt recess 522) configured to receive the biased latch bolt (e.g., biased latch bolt 520) to couple the first MEMS subportion (e.g., first MEMS subportion 500) and the second MEMS subportion (e.g., second MEMS subportion 504) in the latched configuration (as shown in FIG. 5B and FIG. 5D).

As also shown in FIGS. 5C-5D, the electrically-conductive, MEMS flexure assembly (e.g., electrically-conductive, MEMS flexure assembly 32) may include a biasing assembly (e.g., biasing assembly 524) configured to bias the first MEMS subportion (e.g., first MEMS subportion 500) and the second MEMS subportion (e.g., second MEMS subportion 504) in the unlatched configuration (as shown in FIG. 5A and FIG. 5C).

### Piezoelectric Motion Limiters for MEMS Autofocus Actuators

Various autofocus piezoelectric motion limiting features are provided according to aspects of the present disclosure. A piezoelectric autofocus actuator can include integrated in-plane motion limiting features, integrated out-of-plane motion locking features, and/or assembled out-of-plane motion locking features, according to various example embodiments described in detail below with reference to the accompanying drawings.

### PZT AF Actuator—As Fabricated

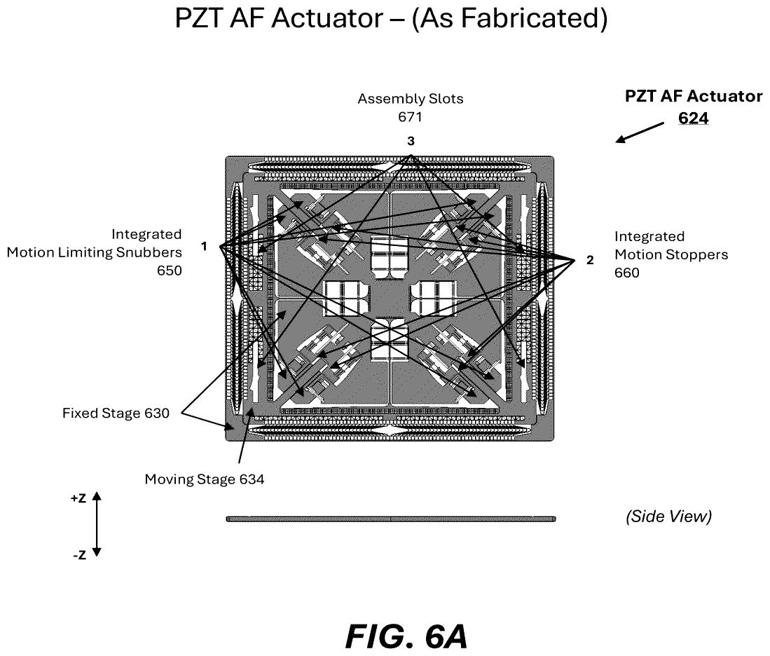

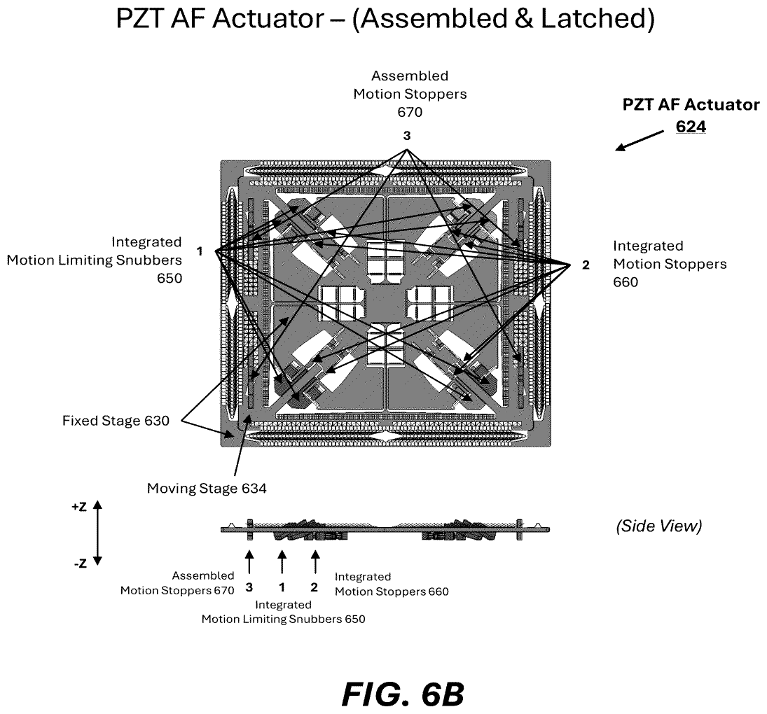

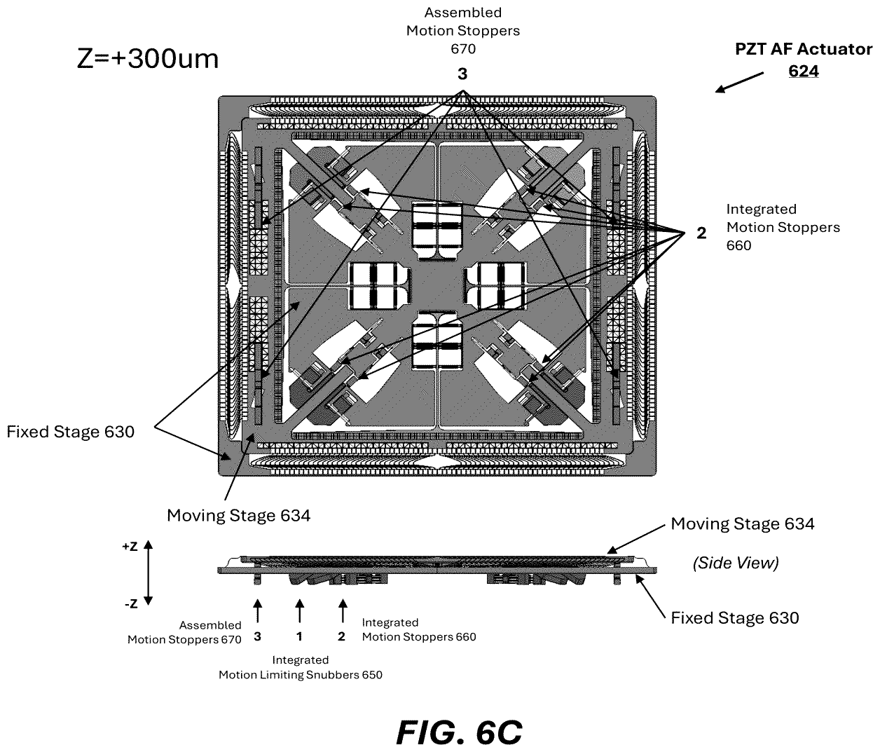

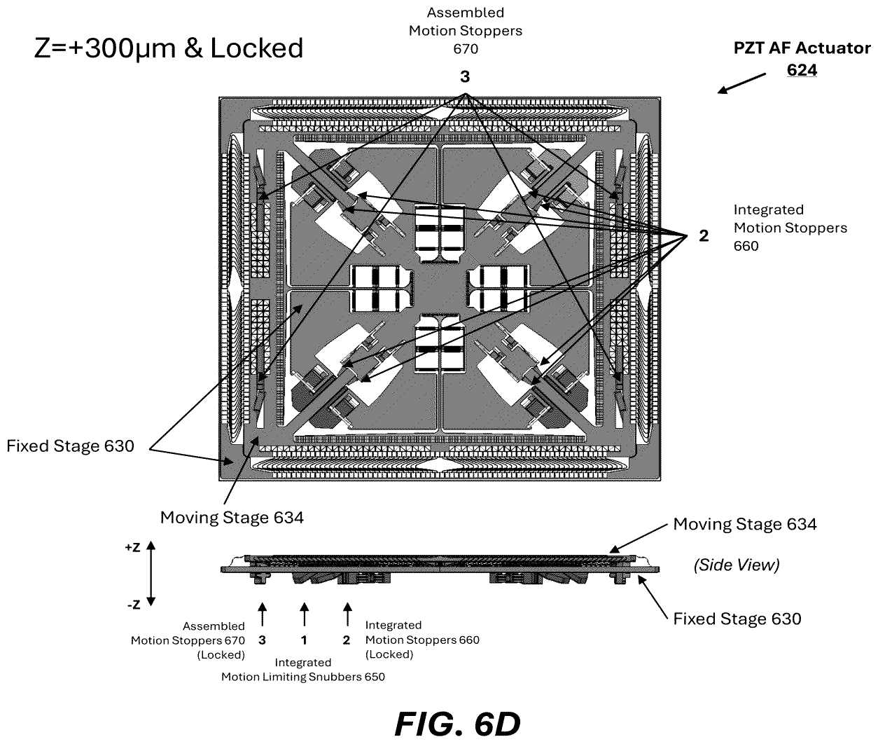

FIG. 6A shows a piezoelectric autofocus actuator 624 (also referred to herein as PZT AF actuator 624), as fabricated, according to an example embodiment of the present disclosure. As shown in FIG. 6A, the PZT AF actuator 624 includes: a fixed stage 630; a moving stage 634; integrated in-plane motion limiting snubbers 650; integrated out-of-plane motion stoppers 660; and assembly slots 671 (for receiving assembled out-of-plane motion stoppers 670, as described further below).

The moving stage 634 is movable along a direction of travel (along the Z-axis), while the fixed stage 630 is non-moving (stationary) and can include a MEMS outer frame (exterior with respect to moving stage 634) and a MEMS inner frame (interior with respect to moving stage 634). The motion limiting snubbers 650 are integrated, passive, in-plane snubbing features for accommodating in-plane snubbing over out-of-plane travel ranges that are larger than the thickness of the die. The motion stoppers 660 are integrated, active, out-of-plane locking features for limiting motion along the travel direction (Z-axis) when the PZT AF actuator 624 is not in operation. When assembled in the assembly slots 671, the motion stoppers 670 are assembled, active, out-of-plane locking features for limiting motion along the travel direction (Z-axis) when the PZT AF actuator 624 is not in operation.

Thus, as fabricated, the PZT AF actuator 624 of FIG. 6A has three motion limiting features for improving drop performance: (1) Integrated, passive, in-plane snubbing features (650) for accommodating in-plane snubbing over out-of-plane travel ranges larger than the thickness of the die; (2) Integrated, active, out-of-plane locking features (660) for limiting motion of the moving stage 634 along the travel direction (Z-axis) when not in operation; and (3) Features to assemble (671) active, out-of-plane locking features (670) for limiting motion of the moving stage 634 along the travel direction (Z-axis) when not in operation.

### PZT AF Actuator—Assembled & Latched

FIG. 6B shows the PZT AF actuator 624, as assembled and latched, according to an example embodiment of the present disclosure. As shown in FIG. 6B, the integrated in-plane motion limiting snubbers 650 have been deployed, the integrated out-of-plane motion stoppers 660 have been deployed, and the assembled out-of-plane motion stoppers 670 have been assembled to the assembly slots 671 in the moving stage 634.

Once deployed, the integrated in-plane motion limiting snubbers 650 are configured to limit in-plane motion of the moving stage 634, even if the moving stage 634 has moved above or below the neutral Z position. Once deployed, the integrated out-of-plane motion stoppers 660 are configured to be actuated to lock (restrict) out-of-plane motion of the moving stage 634 along the Z-axis. Once assembled in the assembly slots 671 of the moving stage 634, the out-of-plane motion stoppers 670 are configured to be actuated to lock (restrict) out-of-plane motion of the moving stage 634 along the Z-axis.

Thus, the PZT AF actuator 624 can be placed in a latched configuration and assembled with the motion stoppers 670, in which: (1) The integrated, in-plane motion limiting features (650) have been deployed to limit the in-plane motion of the moving stage even when the stage has moved above or below the neutral position; (2) The integrated, out-of-plane motion locking mechanisms (660) are deployed and may be actuated to lock the out-of-plane motion (these mechanisms can also be actuated to unlock the device when in use); and (3) The out-of-plane motion locking devices (670) are assembled into assembly slots (671) in the moving stage 634.

### PZT AF Actuator, Z=+300 μm

FIG. 6C shows the PZT AF actuator 624 with the moving stage 634 moving along the Z-axis in the +Z travel direction, according to an example embodiment. In this example, Z=+300 μm, although this disclosure is not limited thereto.

During normal operation of the PZT AF actuator 624, the integrated out-of-plane motion stoppers 660 as well as the assembled out-of-plane motion stoppers 670 are left in their disengaged (unlocked) position so that the moving stage 634 is free to move along the Z-axis (out-of-plane motion).

### PZT AF Actuator, Z=+300 μm & Locked

FIG. 6D shows the PZT AF actuator 624 with the moving stage 634 moved along the Z-axis in the +Z travel direction and locked in its current position, according to an example embodiment. In this example, Z=+300 μm, although this disclosure is not limited thereto.

When the function of the PZT AF actuator 624 is not needed, the integrated out-of-plane motion stoppers 660 as well as the assembled out-of-plane motion stoppers 670 can be actuated to move their respective locking blocks (described below) into position to prevent or minimize any motion along the Z-axis (out-of-plane motion).

### Integrated In-Plane Motion Limiting Snubbers

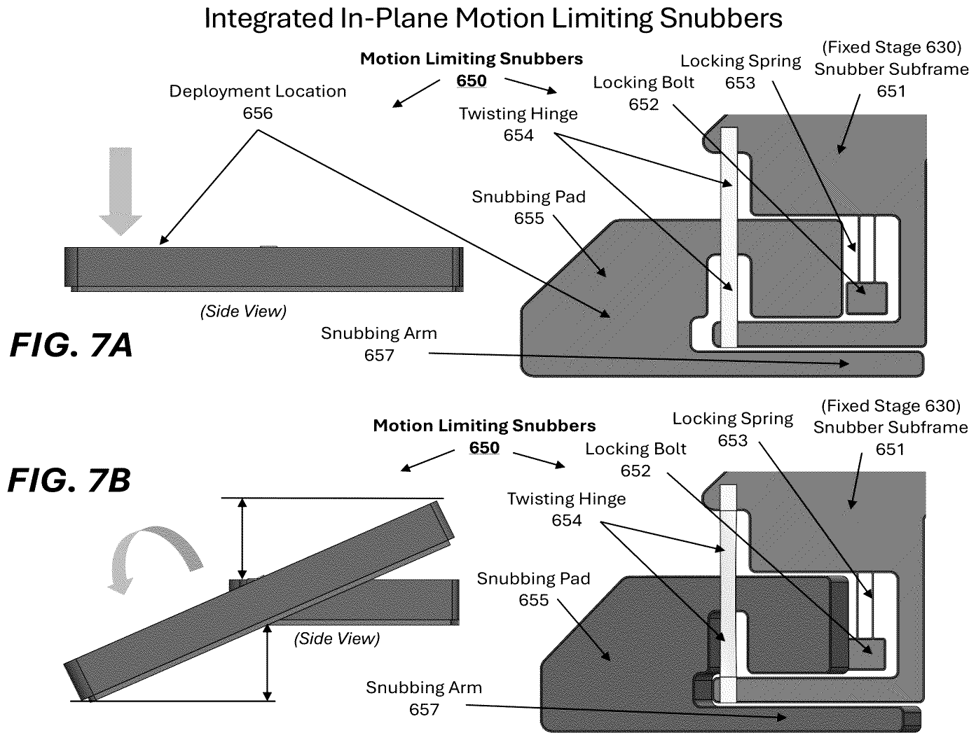

FIG. 7A shows an integrated in-plane motion limiting snubber 650 prior to deployment, and FIG. 7B shows the integrated in-plane motion limiting snubber 650 after deployment, according to an example embodiment of the present disclosure. The integrated in-plane motion limiting snubbers 650 include a snubber subframe 651, a locking bolt 652, a locking spring 653, a twisting hinge 654, and a snubbing pad 655 with a snubbing arm 657.

As shown in FIG. 7A, the integrated in-plane motion limiting snubbers 650 are initially fabricated in a flat position. The snubber subframe 651 is an integrated portion of the fixed stage 630 (e.g., MEMS inner frame) that is designed to accommodate the various components of the integrated motion limiting snubbers 650. When the deployment location 656 is pressed, the snubbing pad 655 and the snubbing arm 657 rotate around the axis of the twisting hinge 654. While rotating, the locking spring 653 will deform and the locking bolt 652 will slide away.

As shown in FIG. 7B, the snubbing arm 657 extends above the original part and the snubbing pad 655 extends below the original part to restrict in-plane motion of the moving stage 634 even when the moving stage 634 is above or below the original silicon plane. When the snubbing arm 657 (and/or the snubbing pad 655) reaches the desired rotation, the locking bolt 652 will re-engage and lock the snubbing arm 657 and the snubbing pad 655 in place. This mechanism can be further reinforced with epoxy.

### Integrated Out-of-Plane Motion Stopper

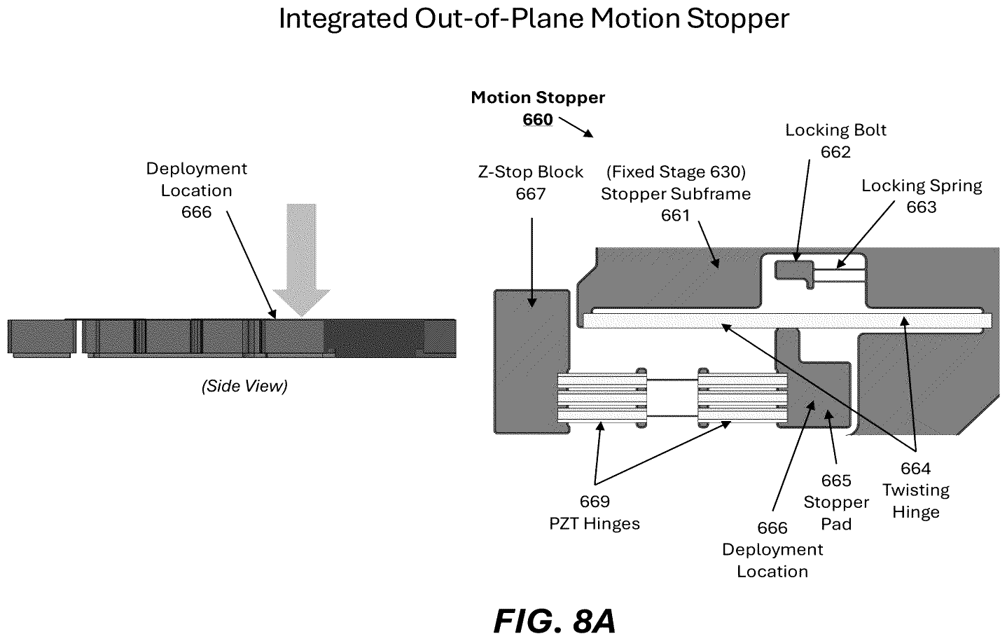

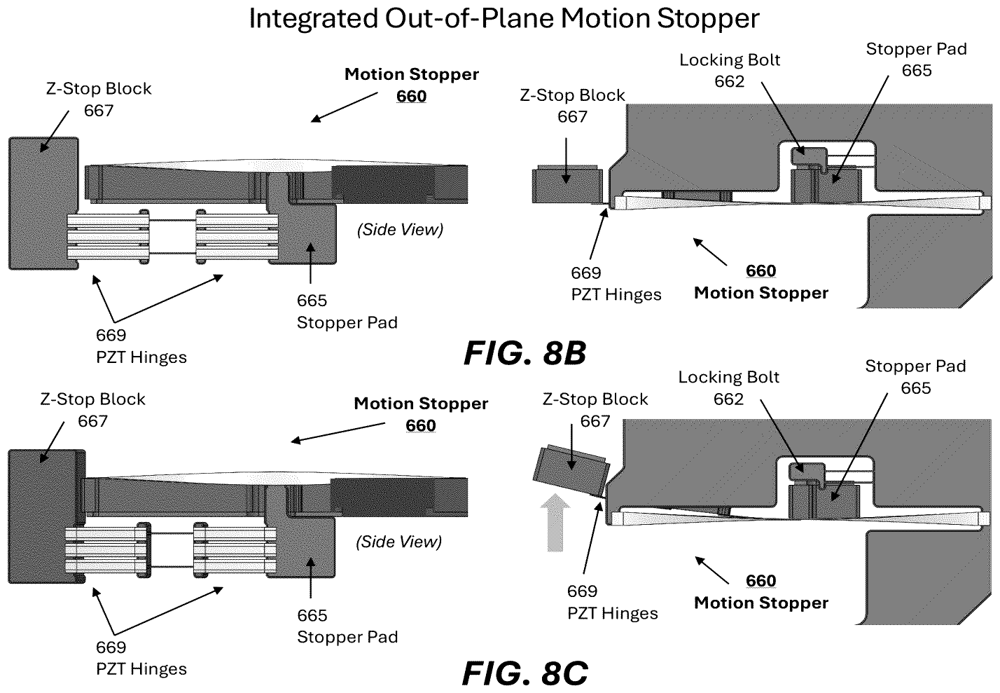

FIGS. 8A-8C show an integrated out-of-plane motion stopper 660, according to an example embodiment of the present disclosure. The integrated out-of-plane motion stoppers 660 include a stopper subframe 661, a locking bolt 662, a locking spring 663, a twisting hinge 664, a stopper pad 665, a Z-stop block 667, and PZT hinges 669.

As shown in FIG. 8A, the integrated out-of-plane motion stoppers 660 are initially fabricated in a flat position. The stopper subframe 661 is an integrated portion of the fixed stage 630 (e.g., MEMS inner frame) that is designed to accommodate the various components of the integrated motion stoppers 660. When the deployment location 666 is pressed, the stopper pad 665 (and the Z-stop block 667) rotates around the axis of the twisting hinge 664. While rotating, the locking spring 663 will deform and the locking bolt 662 will slide away.

As shown in FIG. 8B, when the stopper pad 665 reaches the desired rotation, the locking bolt 662 will re-engage and lock the stopper pad 665 in place. This mechanism can be further reinforced with epoxy.

As shown in FIG. 8C, applying a voltage to the PZT hinges 669 will move the Z-stop block 667. When the MEMS PZT AF actuator 624 is not in operation, the Z-stop block 667 can be moved under the moving stage 634 to limit (restrict) motion in the actuator travel direction.

### Out-of-Plane Motion Stopper

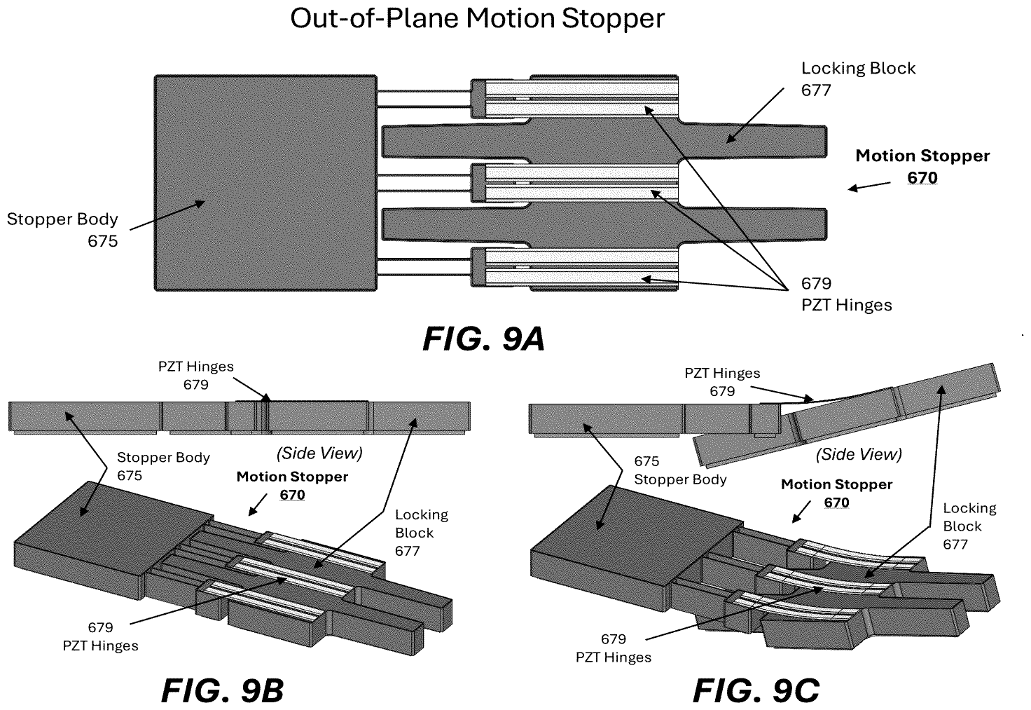

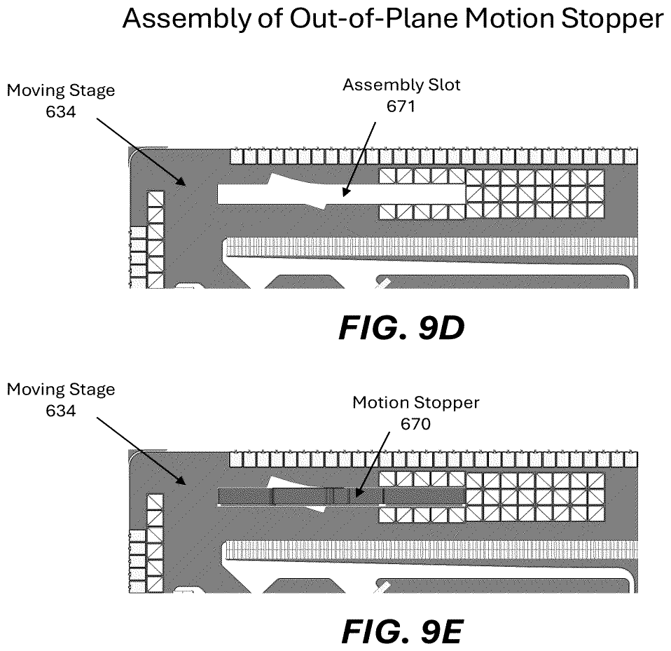

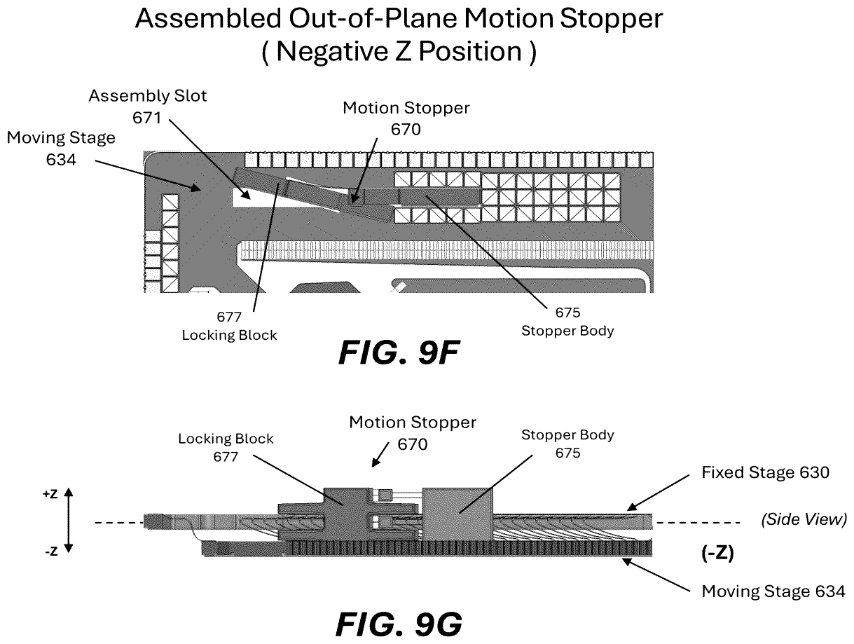

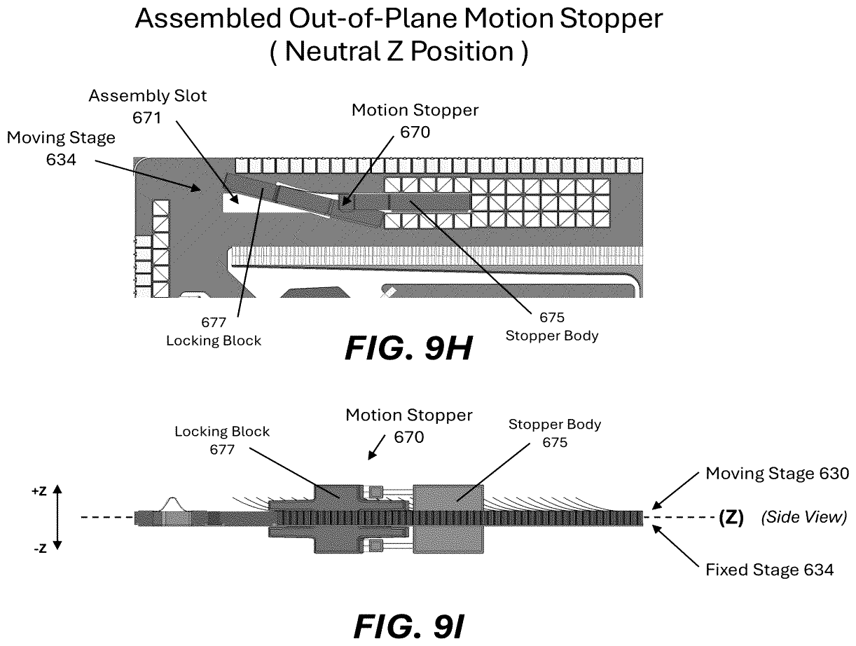

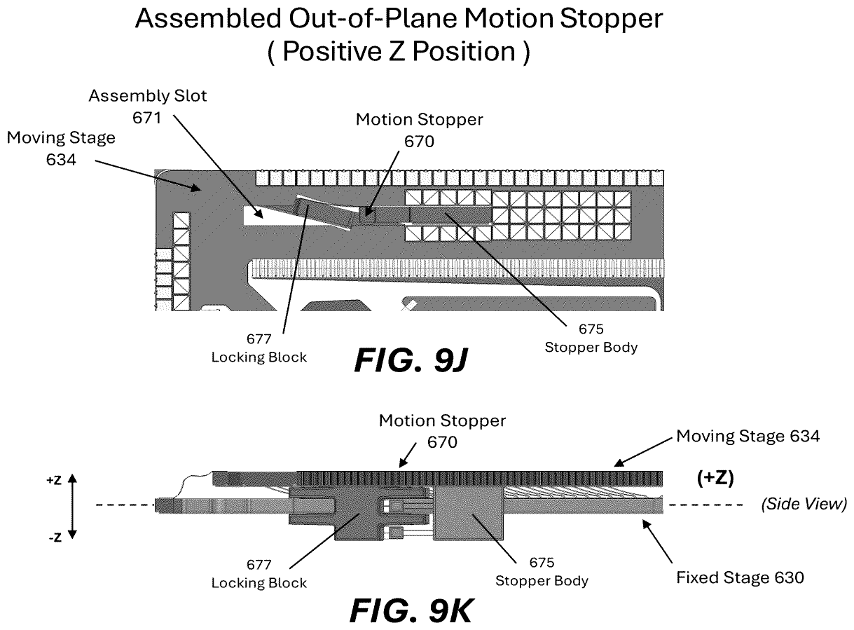

FIGS. 9A-9C show an out-of-plane motion stopper 670 prior to being assembled, according to an example embodiment of the present disclosure. The out-of-plane motion stopper 670 includes a stopper body 675, a locking block 677, and PZT hinges 679. The locking block 677 is movable with respect to the stopper body 675 by actuating the PZT hinges 679.

FIG. 9A is a top view of the out-of-plane motion stopper 670 prior to deployment. FIG. 9B is a side view and a perspective view of the out-of-plane motion stopper 670 in a disengaged (unlocked) position before actuation. FIG. 9C is a side view and a perspective view of the out-of-plane motion stopper 670 in an engaged (locked) position after actuation.

The out-of-plane motion stopper 670 of FIGS. 9A-9C can be assembled to the PZT AF actuator 624 to restrict out-of-plane motion (along the Z-axis) in multiple discrete locations, as further described below with reference to FIGS. 9D-9K.

### Assembled Out-of-Plane Motion Stopper

FIG. 9D shows an assembly slot 671 in the moving stage 634 of the PZT AF actuator 624 to accommodate the out-of-plane motion stopper 670 described above with reference to FIGS. 9A-9C, prior to assembly and deployment thereof.

FIG. 9E shows the out-of-plane motion stopper 670 as assembled in the assembly slot 671 of the moving stage 634 of the PZT AF actuator 624. It should be noted that the assembled out-of-plane motion stopper 670 is rigidly connected to the same substrate as the fixed stage 630 and does not move with the moving stage 634. Additionally, the assembled out-of-plane motion stopper 670 restricts motion orthogonal to the travel direction. This essentially functions as an in-plane motion limiter and the effect is present regardless of whether the motion stopper has been actuated or not.

The assembled out-of-plane motion stopper 670 may have features to enable locking in several discrete positions, as shown in FIGS. 9F-9G, FIGS. 9H-9I, and FIGS. 9J-9K, respectively.

FIG. 9F is a top view and FIG. 9G is a side view, respectively, showing the assembled out-of-plane motion stopper 670 active when the moving stage 634 is in the negative Z (−Z) travel position. As shown in FIGS. 9F-9G, the locking block 677 of the assembled out-of-plane motion stopper 670 has been actuated to the engaged (locked) position while the moving stage 634 is in the −Z position.

FIG. 9H is a top view and FIG. 9I is a side view, respectively, showing the assembled out-of-plane motion stopper 670 active when the moving stage 634 is in the neutral Z travel position. As shown in FIGS. 9H-9I, the locking block 677 of the assembled out-of-plane motion stopper 670 has been actuated to the engaged (locked) position while the moving stage 634 is in the Z position.

FIG. 9J is a top view and FIG. 9K is a side view, respectively, showing the assembled out-of-plane motion stopper 670 active when the moving stage 634 is in the positive Z (+Z) travel position. As shown in FIGS. 9J-9K, the locking block 677 of the assembled out-of-plane motion stopper 670 has been actuated to the engaged (locked) position while the moving stage 634 is in the +Z position.

### Top & Section Views of Motion Limiters & Motion Stoppers

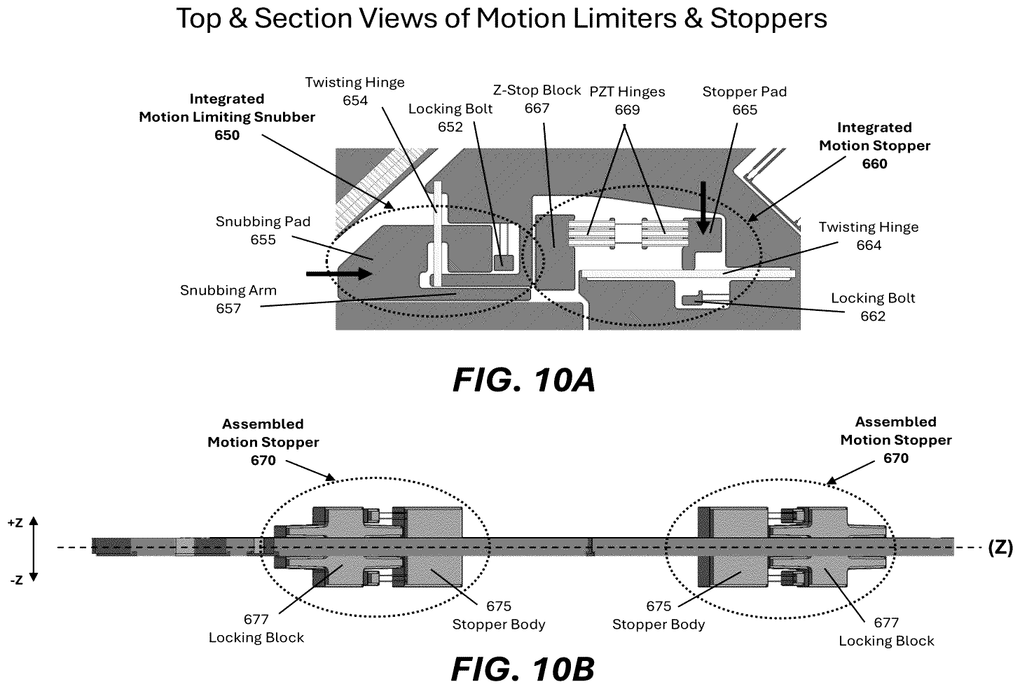

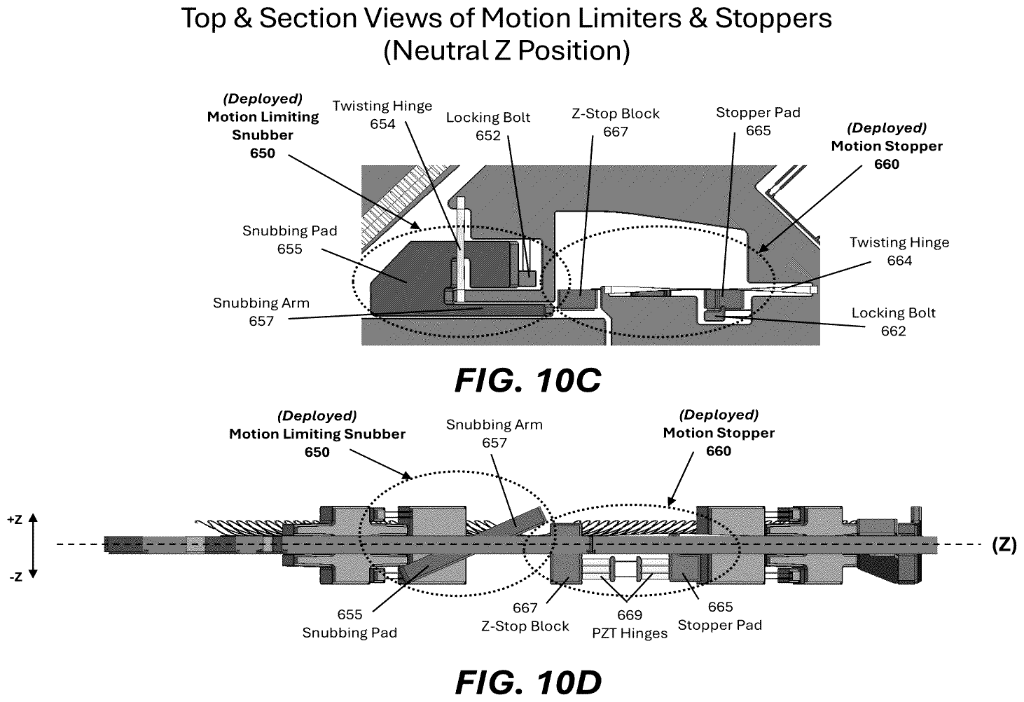

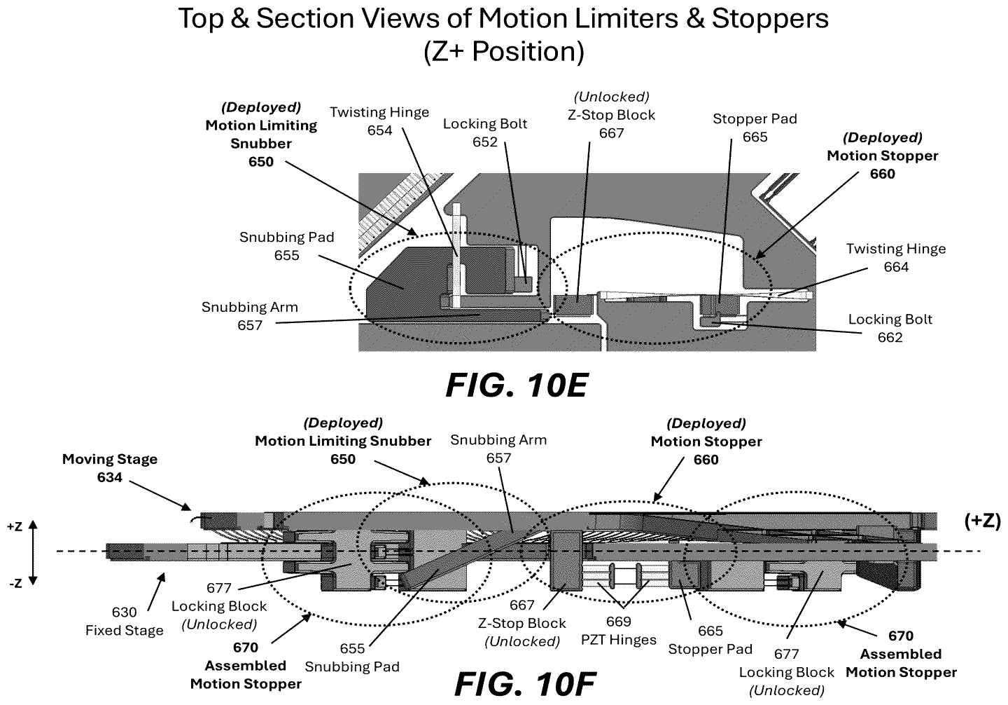

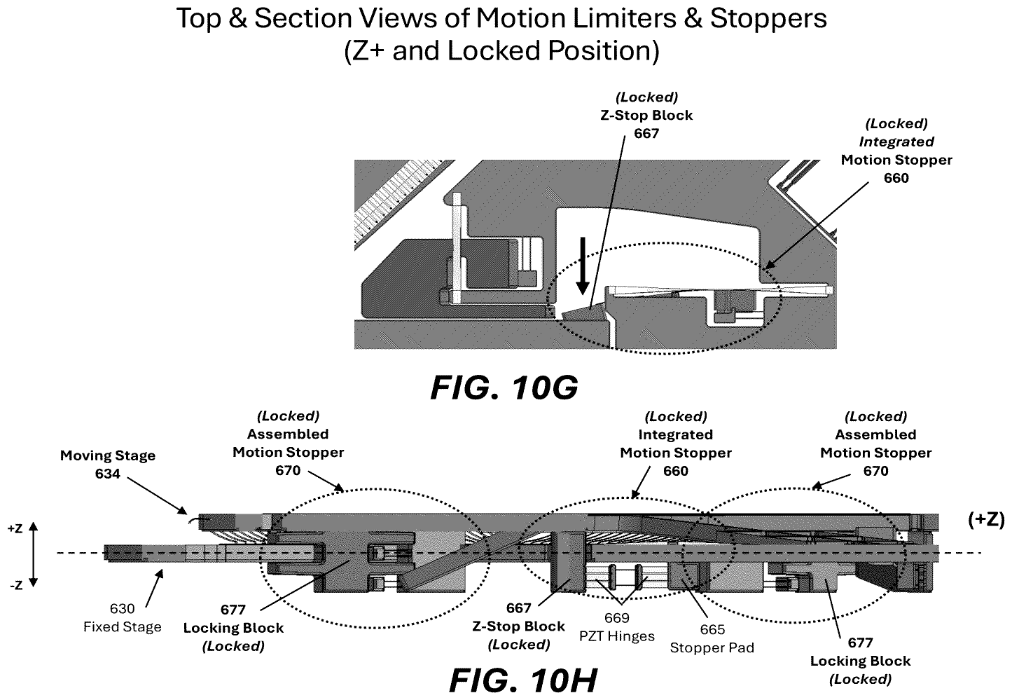

With continued reference to FIGS. 6A, 6B, 7A, 8A, 9A-9B and 9E, also refer to FIG. 10A, which shows a top view of the PZT AF actuator 624 with the integrated motion limiting snubber 650 and the integrated motion stopper 660 in the flat as-fabricated condition, together with FIG. 10B, which shows a side view of the PZT AF actuator 624 assembled with the out-of-plane motion stoppers 670, according to an example embodiment of the present disclosure.

With continued reference to FIGS. 6B, 7B, 8B, 9A-9B, and 9H-9I, also refer to FIG. 10C, which shows a top view of the PZT AF actuator 624 after deploying the integrated motion limiting snubber 650 and the integrated motion stopper 660, respectively, and FIG. 10D which shows a side view of the PZT AF actuator 624 after assembling the out-of-plane motion stoppers 670 and deploying the integrated motion limiting snubber 650 and the integrated motion stopper 660, respectively, according to an example embodiment of the present disclosure. In FIGS. 10C-10D, the moving stage 634 remains in the neutral Z travel position.

With continued reference to FIGS. 6C, 7B, 8B, 9A-9B, and 9J-9K, also refer to FIG. 10E, which shows a top view of the PZT AF actuator 624 after deploying the integrated motion limiting snubber 650 and the integrated motion stopper 660, respectively, together with FIG. 10F, which shows a side view of the PZT AF actuator 624 after assembling the out-of-plane motion stoppers 670 and deploying the integrated motion limiting snubber 650 and the integrated motion stopper 660, respectively, according to an example embodiment of the present disclosure. In FIGS. 10E-10F, the moving stage 634 has now moved along the Z-axis (out-of-plane motion) to the +Z travel position.

With continued reference to FIGS. 6D, 7B, 8C, 9A, 9C and 9J-9K, also refer to FIG. 10G, which shows a top view of the PZT AF actuator 624 after locking the integrated motion stopper 660, together with FIG. 10H, which shows a side view of the PZT AF actuator 624 after locking the integrated motion stopper 660 and locking the assembled motion stopper 670, respectively, according to an example embodiment of the present disclosure. As shown, the moving stage 634 has moved along the Z-axis (out-of-plane motion) to the +Z travel position. Additionally, the integrated motion stopper 660 has been engaged (i.e., actuated to move the Z-stop block 667 into the locked position) and the assembled motion stoppers 670 have been engaged (i.e., actuated to move the locking blocks 677 into the locked position) to lock the position of the moving stage 634 in FIGS. 10G-10H, and thereby restrict movement of the moving stage 634 along the Z-axis.

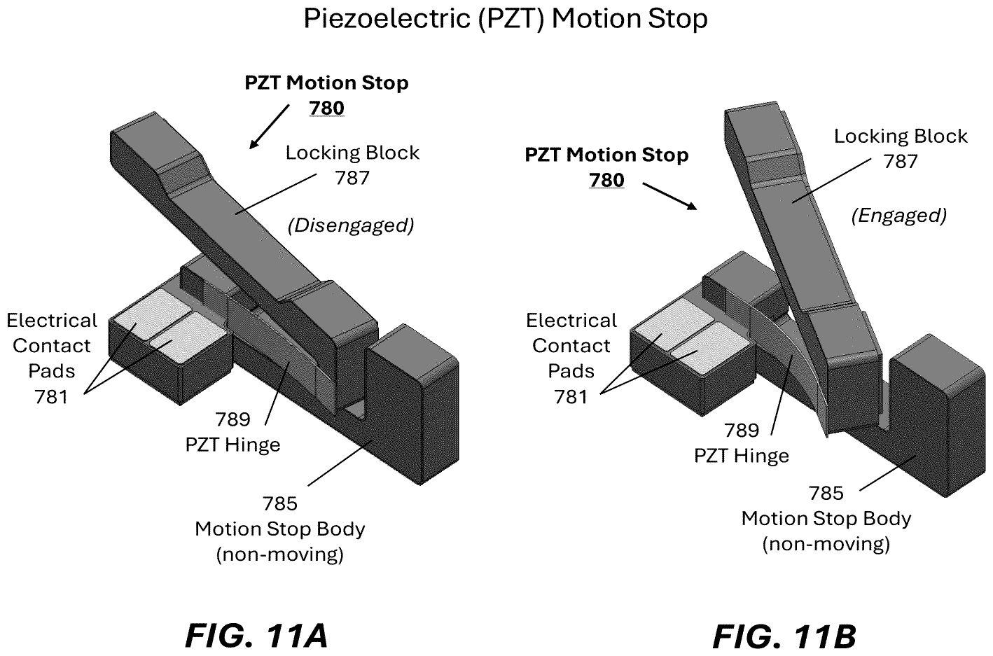

Thus, assembled out-of-plane motion stoppers 670 have been described according to an example embodiment above. However, the present disclosure is not limited thereto, and another assembled out-of-plane motion stopper (e.g., refer to PZT motion stop 780 below) according to an alternative example embodiment will now be described with reference to FIGS. 11A-11B, FIGS. 12A-12B, and FIGS. 13A-13E, respectively.

### PZT Motion Stop

An out-of-plane piezoelectric (PZT) motion stopper that can be assembled to a MEMS autofocus (AF) actuator is provided according to another aspect of the present disclosure.

FIGS. 11A-11B show a PZT motion stop 780, according to an example embodiment of the present disclosure. The PZT motion stops 780 can be assembled with a MEMS AF actuator, as will be described further below.

As shown in FIG. 11A, the PZT motion stop 780 includes a pair of electrical contact pads 781, a motion stop body 785 (non-moving), a locking block 787 (moving), and a PZT hinge 789 connecting the motion stop body 785 and the locking block 787.

As shown in FIG. 11B, the PZT motion stop 780 can be actuated by applying a voltage differential between the two electrical contact pads 781, which causes the PZT hinge 789 to bend and thereby moves the locking block 787.

### Assembly of PZT Motion Stop

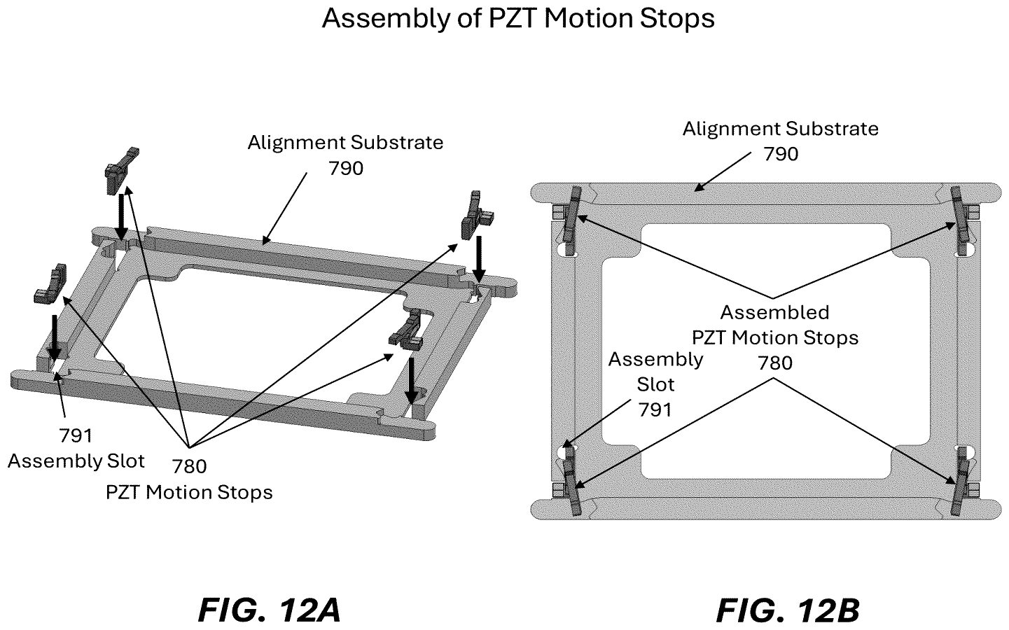

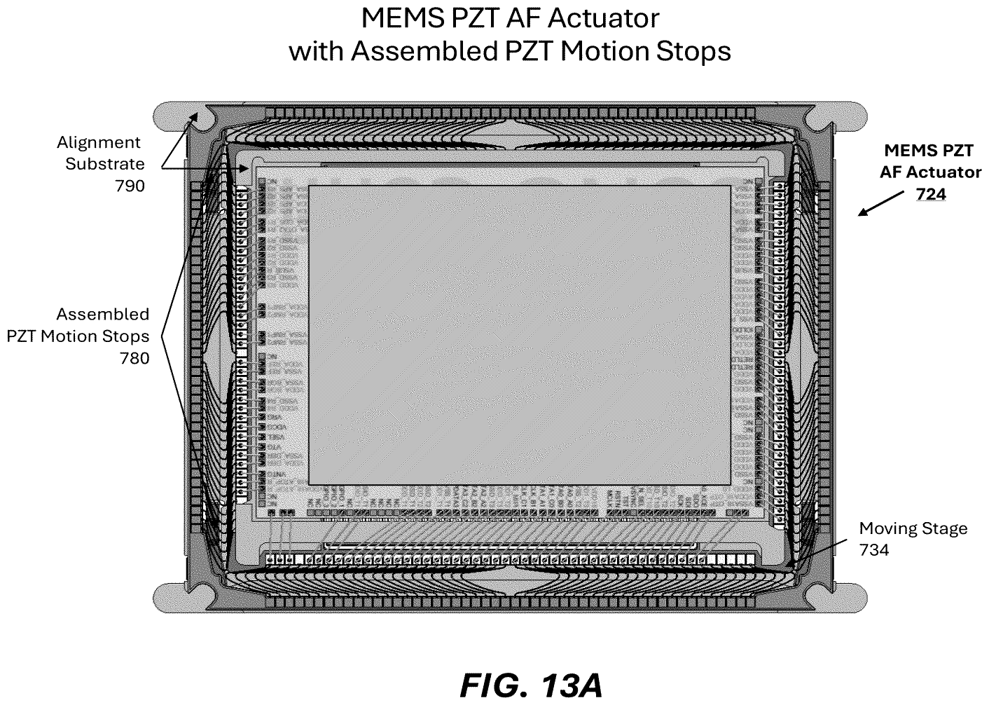

FIG. 12A is a perspective view and FIG. 12B is a top view, respectively, showing assembly of the PZT motion stops 780 to an alignment substrate 790, according to an example embodiment of the present disclosure.

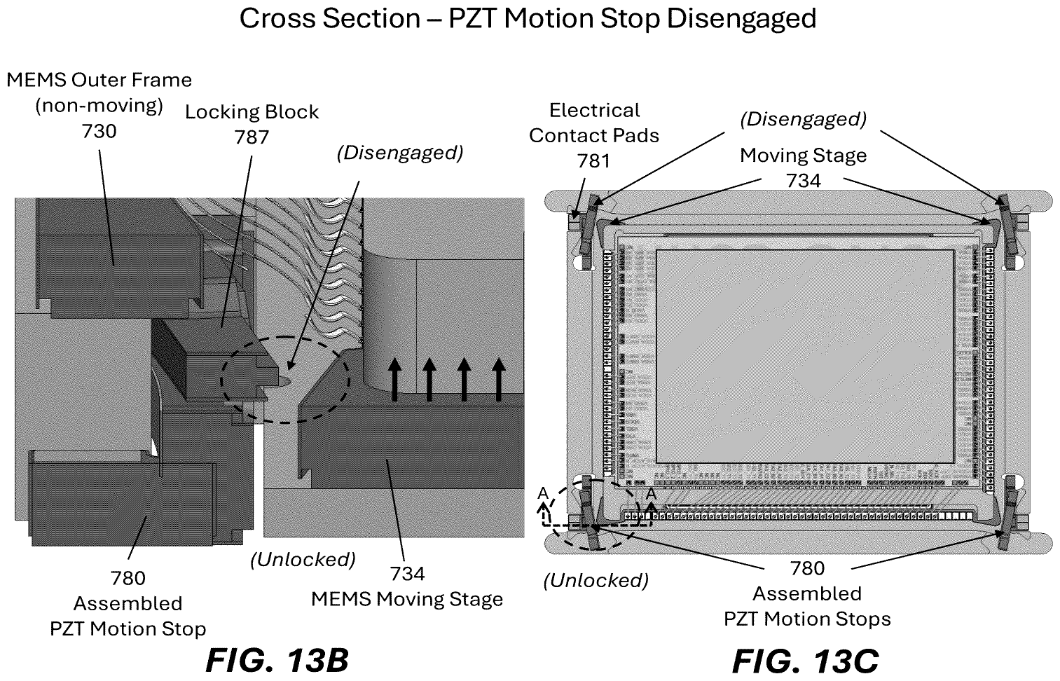

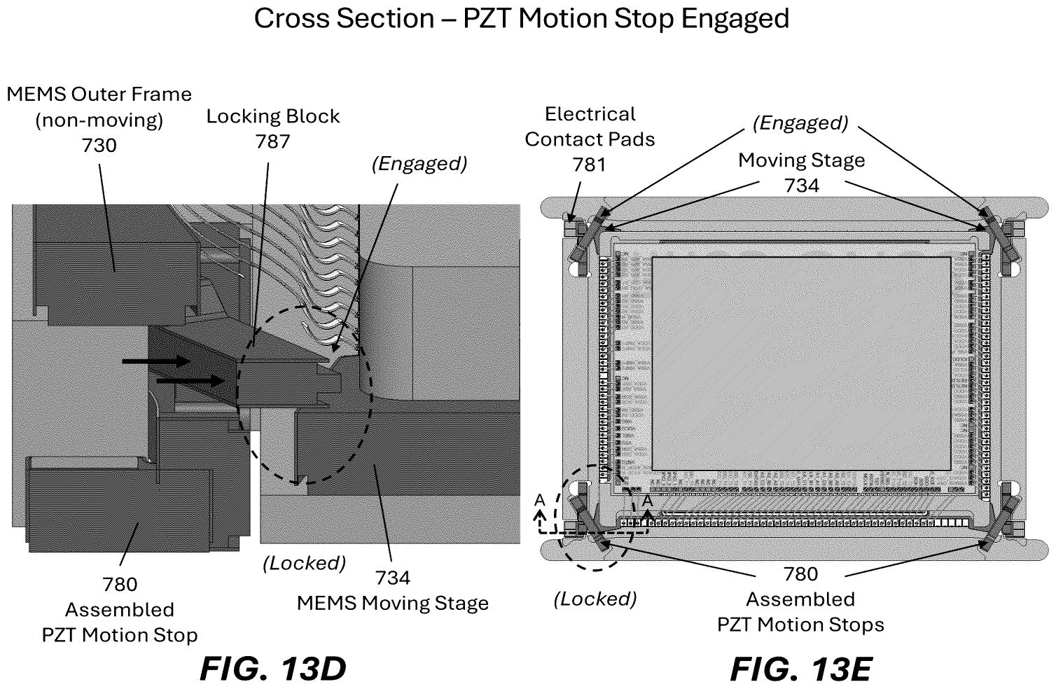

In this example, one or more PZT motion stops 780 (e.g., four are shown) may be assembled to the alignment substrate 790, which together are referred to as PZT motion stop sub-assembly. The PZT motion stop sub-assembly can be assembled to a MEMS AF actuator, as described next with reference to FIG. 13A.

### MEMS AF Actuator With Assembled PZT Motion Stops

FIG. 13A shows a MEMS AF actuator 724 with assembled PZT motion stops 780, according to an example embodiment of the present disclosure. As shown in FIG. 13A, the MEMS AF actuator 724 can be assembled to the PZT motion stop sub-assembly of the PZT motion stops 780 together with the alignment substrate 790. After assembly, the assembled PZT motion stops 780 can be actuated (by applying a voltage differential between the two electrical contact pads 781) to limit the motion of the MEMS AF actuator 724 in the Z-direction.

In this example, the fixed stage 730 (MEMS outer frame 730) sits above the PZT motion stops 780. The moving stage 734 can be actuated to move in the out-of-plane direction (along the Z-axis) when the assembled PZT motion stops 780 are disengaged (unlocked), whereas such motion of the moving stage 734 in the Z-direction is limited (restricted) when the assembled PZT motion stops 780 are engaged (locked).

### Cross Section—Assembled PZT Motion Stops Disengaged

FIG. 13B is a side view and FIG. 13C is a top view, respectively, showing the assembled PZT motion stop 780 when disengaged, according to an example embodiment of the present disclosure. FIG. 13B is a cross-sectional view taken at line A-A in FIG. 13C. As shown in FIGS. 13B-13C, the MEMS moving stage 734 is free to move in the Z-direction while the locking block 787 of the PZT motion stop 780 is in the disengaged (unlocked) position.

### Cross Section—Assembled PZT Motion Stops Engaged

FIG. 13D is a side view and FIG. 13E is a top view, respectively, showing the assembled PZT motion stop 780 when engaged, according to an example embodiment of the present disclosure. FIG. 13D is a cross-sectional view taken at line A-A in FIG. 13E. As shown in FIGS. 13D-13E, after actuation of the PZT motion stop 780 (by applying a voltage to the electrical contact pads 781 to bend the PZT hinges 789), the MEMS moving stage 734 is blocked (restricted) from moving in the Z-direction while the locking block 787 of the PZT motion stop 780 is in the engaged (locked) position.

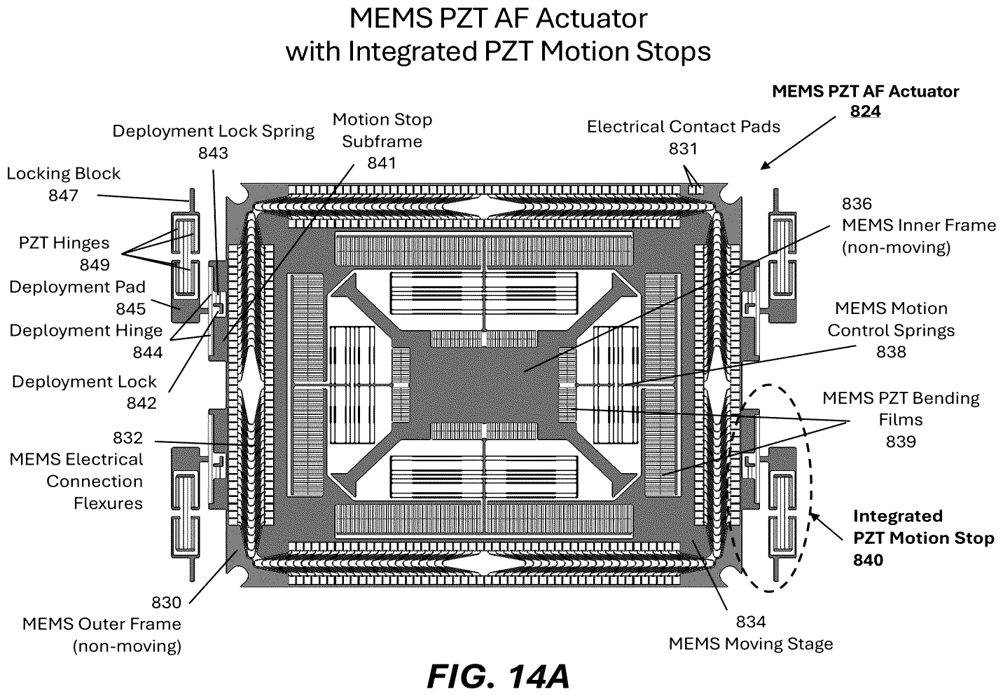

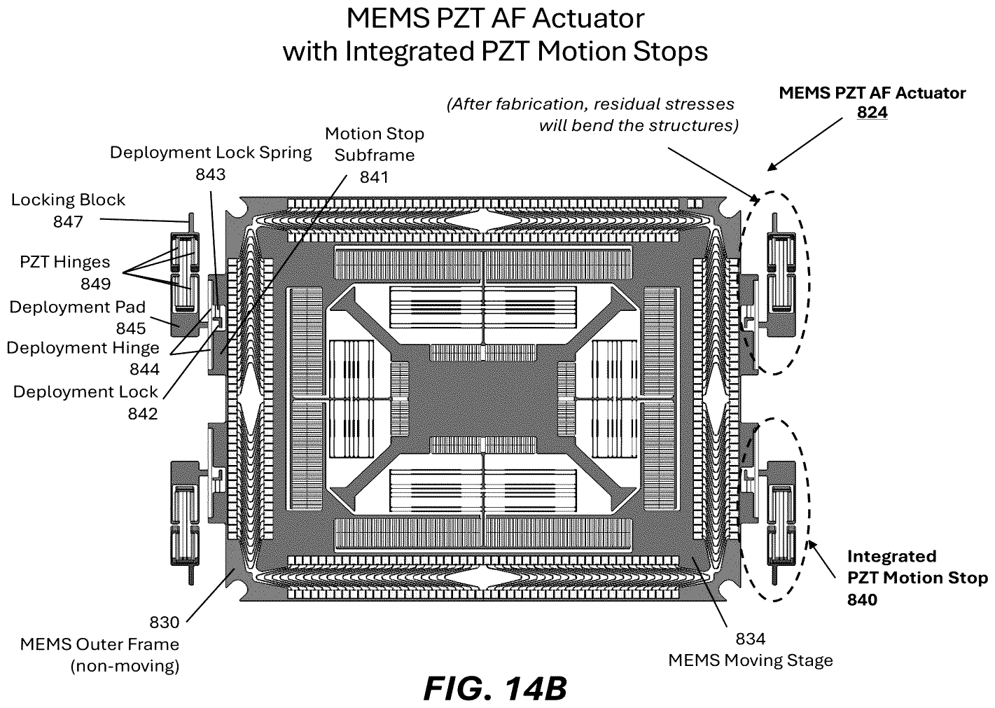

Thus, a MEMS AF actuator 724 with assembled out-of-plane PZT motion stops 780 have been described according to another example embodiment above. However, the present disclosure is not limited thereto, and a MEMS PZT AF actuator with integrated out-of-plane PZT motion stops (e.g., refer to PZT motion stop 840 below) according to yet another example embodiment will now be described with reference to FIGS. 14A-14B, FIGS. 15A-15F, FIGS. 16A-16E, FIGS. 17A-17B, and FIGS. 18A-18E, respectively.

### Integrated PZT Motion Stops

An out-of-plane piezoelectric (PZT) motion stopper that is integrated with a MEMS PZT autofocus (AF) actuator is provided according to yet another aspect of the present disclosure.

FIG. 14A shows a MEMS PZT AF actuator 824 with integrated PZT motion stops 840, as fabricated, according to an example embodiment of the present disclosure. As shown in FIG. 14A, the MEMS PZT AF actuator 824 includes: a MEMS outer frame 830 (non-moving), with electrical contact pads 831; MEMS electrical connection flexures 832; a MEMS moving stage 834; a MEMS inner frame 836 (non-moving); MEMS motion control springs 838; MEMS PZT bending films 839; and integrated PZT motion stops 840.

As noted, the MEMS PZT AF actuator 824 includes a motion control system (e.g., MEMS motion control springs 838) coupling the fixed stage to the moving stage, and piezoelectric bending elements (e.g., MEMS PZT bending films 839) configured to deform the motion control system, and thereby control the precise position on the moving stage 834 relative to the fixed stage (e.g., MEMS outer frame 830 and MEMS inner frame 836).

Still referring to FIG. 14A, the integrated PZT motion stops 840 include: a motion stop subframe 841, a deployment lock 842, a deployment lock spring 843, a deployment hinge 844, a deployment pad 845, a locking block 847, and PZT hinges 849. After fabrication, the residual stresses will bend the structures (e.g., the PZT hinges 849, etc.).

The motion stop subframe 841 is an integrated portion of the MEMS outer frame 830 (e.g., fixed stage) that is designed to accommodate the various components of the integrated PZT motion stops 840. Alternatively, the motion stop subframe 841 can be a separate extension from the MEMS outer frame 830 (fixed stage) that is fabricated separately from the frame and fixedly attached thereto.

FIG. 14B shows the MEMS PZT AF actuator 824 with the integrated PZT motion stops 840 of FIG. 14A experiencing residual stresses after fabrication. As shown in FIG. 14B, after fabrication, the residual stresses will bend the structures of the PZT motion stop 840 (e.g., the PZT hinges 849, the locking blocks 847, etc.).

### Deployment of Integrated PZT Motion Stops

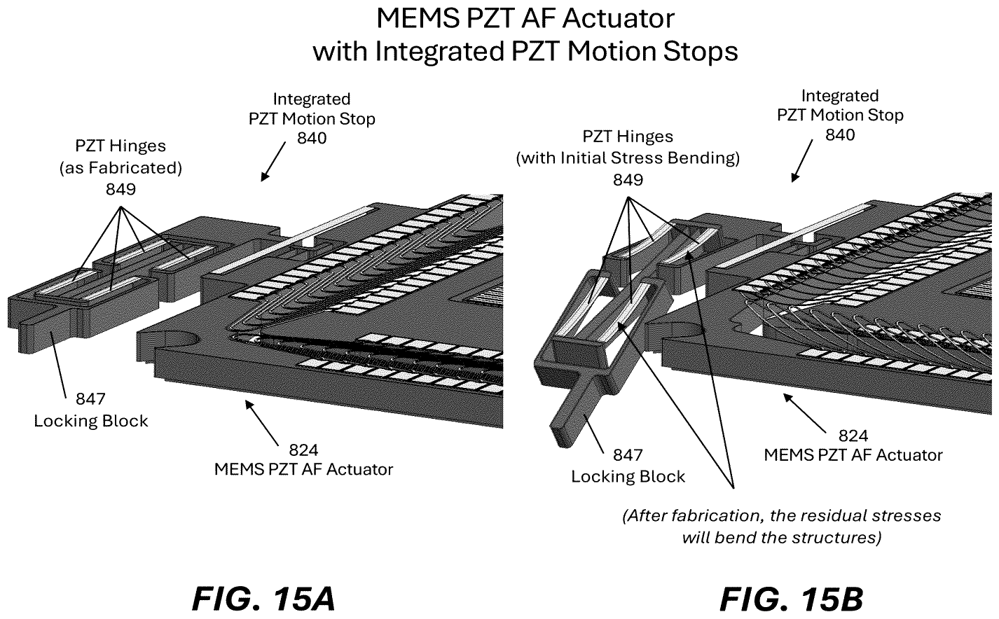

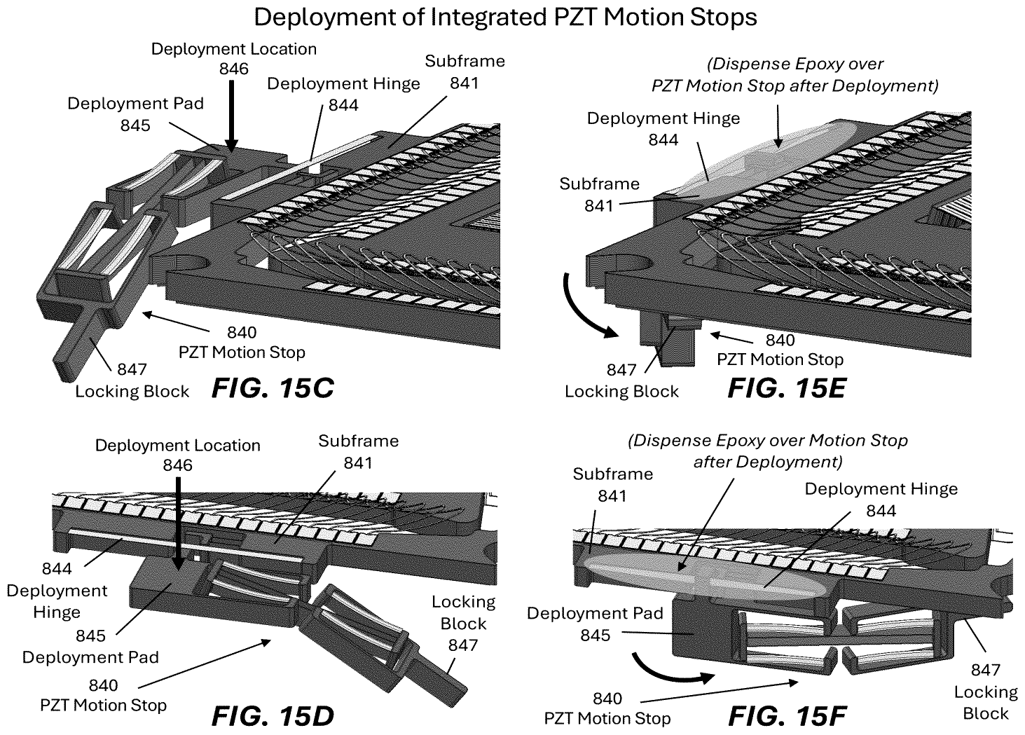

FIG. 15A shows the MEMS PZT AF actuator 824 with the integrated PZT motion stop 840 as fabricated according to the example embodiment described above with reference to FIG. 14A, and FIG. 15B shows the MEMS PZT AF actuator 824 with initial stress bending of structures of the integrated PZT motion stop 840 according to the example embodiment described above with reference to FIG. 14B. After fabrication, the residual stresses will bend the structures, including but not limited to the PZT hinges 849, as shown in FIG. 15B.

FIG. 15C and FIG. 15D are views from two different angles, respectively, showing deployment of the integrated PZT motion stop 840, according to an example embodiment of the present disclosure. As shown in FIGS. 15C-15D, a deployment tool (not shown) can be used to push on the deployment pad 845 to rotate the integrated PZT motion stop 840 to the deployed position. The deployment lock 842 and the deployment lock spring 843 will hold the deployment pad 845 of the integrated PZT motion stop 840 in place, while this mechanism can be reinforced by encapsulating with epoxy.

FIG. 15E and FIG. 15F are views from two different angles, respectively, showing the dispensing of epoxy over the integrated PZT motion stop 840 after the deployment, according to an example embodiment of the present disclosure. As shown in FIGS. 15E-15F, epoxy can be dispensed over the integrated PZT motion stop 840 (e.g., over the deployment lock 842, the deployment lock spring 843, the deployment hinge 844, a surface of the deployment pad 845, and at least part of the surrounding surface of the motion stop subframe 841) after deployment thereof, to reinforce the mechanism.

### Integrated PZT Motion Stop—Closeup View

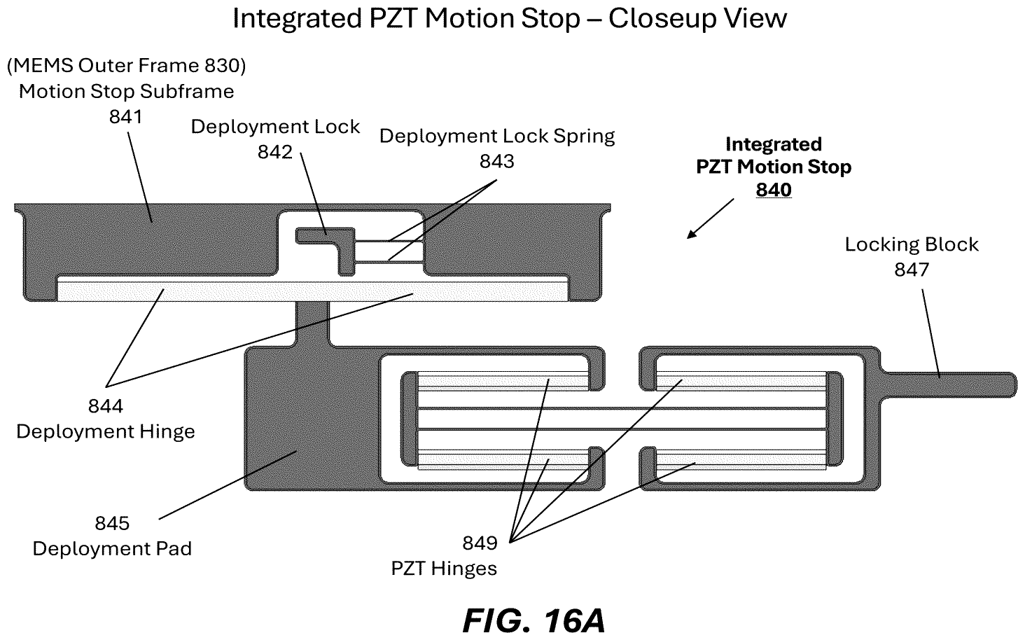

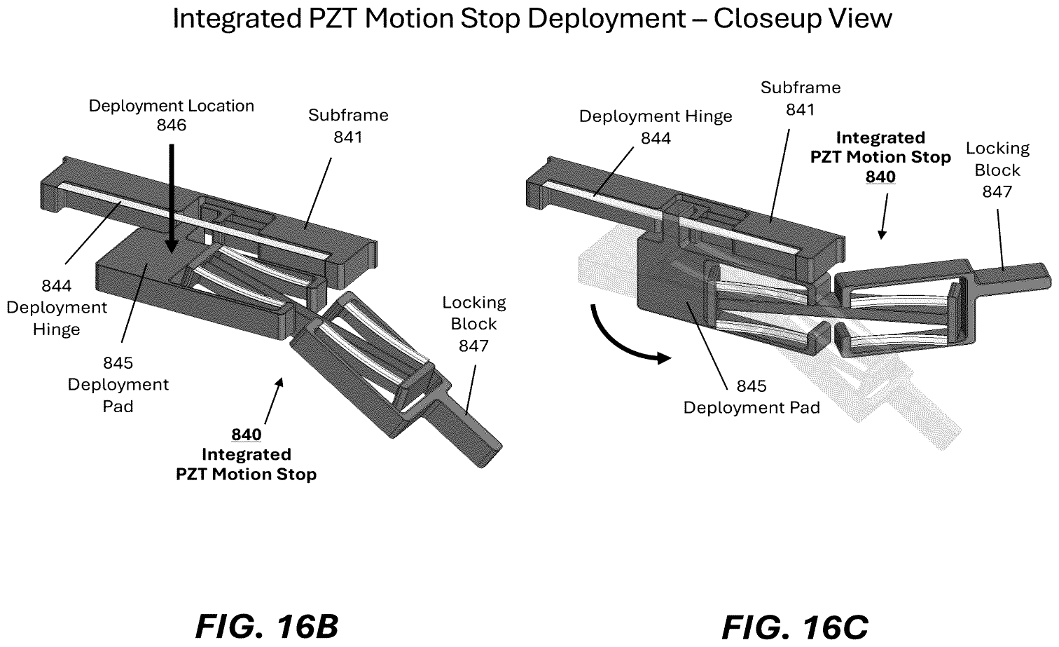

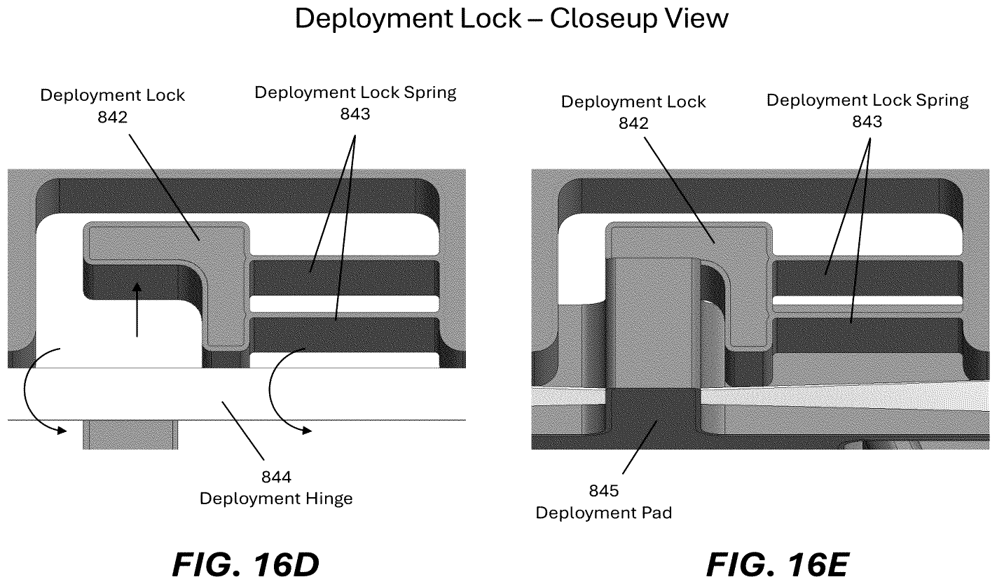

FIG. 16A is a closeup view showing the integrated PZT motion stop 840 as fabricated and prior to deployment, according to the example embodiment described above with reference to FIG. 14A and FIG. 15A. As shown in FIG. 16A, the integrated PZT motion stop 840 includes: the motion stop subframe 841, the deployment lock 842, the deployment lock spring 843, the deployment hinge 844, the deployment pad 845 (i.e., deployment location 846), the locking block 847, and PZT hinges 849.

As noted, the motion stop subframe 841 is an integrated portion of (or an extension from) the MEMS outer frame 830 (e.g., fixed stage) that is designed to accommodate the various components (e.g., the deployment lock 842, the deployment lock spring 843, the deployment hinge 844, the deployment pad 845, etc.) of the integrated PZT motion stops 840.

### Integrated PZT Motion Stop Deployment—Closeup View

FIG. 16B is a closeup view showing the integrated PZT motion stop 840 before deployment according to the example embodiment described above with reference to FIGS. 15B-15D, and FIG. 16C is a closeup view showing the integrated PZT motion stop 840 after deployment according to the example embodiment described above with reference to FIGS. 15C-15F.

As noted above and shown in FIGS. 16B-16C, a deployment tool (not shown) can be used to push on the deployment pad 845 to rotate the integrated PZT motion stop 840 to the deployed position. The deployment lock 842 and the deployment lock spring 843 will hold the deployment pad 845 of the integrated PZT motion stop 840 in place, while the mechanism can be reinforced by encapsulating with epoxy, as noted above.

### Deployment Lock—Closeup View

FIG. 16D is a closeup view showing operation of the deployment lock 842 of the PZT motion stop 840 in the unlocked position, and FIG. 16E is a closeup view showing the deployment lock 842 and the deployment pad 845 of the PZT motion stop 840 in the locked position, according to an example embodiment of the present disclosure.

Referring to FIGS. 16A-16E, during the deployment of the PZT motion stop 840, the mechanism of the PZT motion stop 840 rotates around the axis of the deployment hinge 844. During this rotation, the deployment lock 842 is deformed as the bottom edge of the deployment pad 845 contacts and presses against it as shown in FIG. 16D. Finally, the deployment lock 842 engages with the bottom face of the deployment pad 845 as shown in FIG. 16E, holding in place until the epoxy can be dispensed as described above.

### Deployment of Moving Stage & Integrated PZT Motion Stops

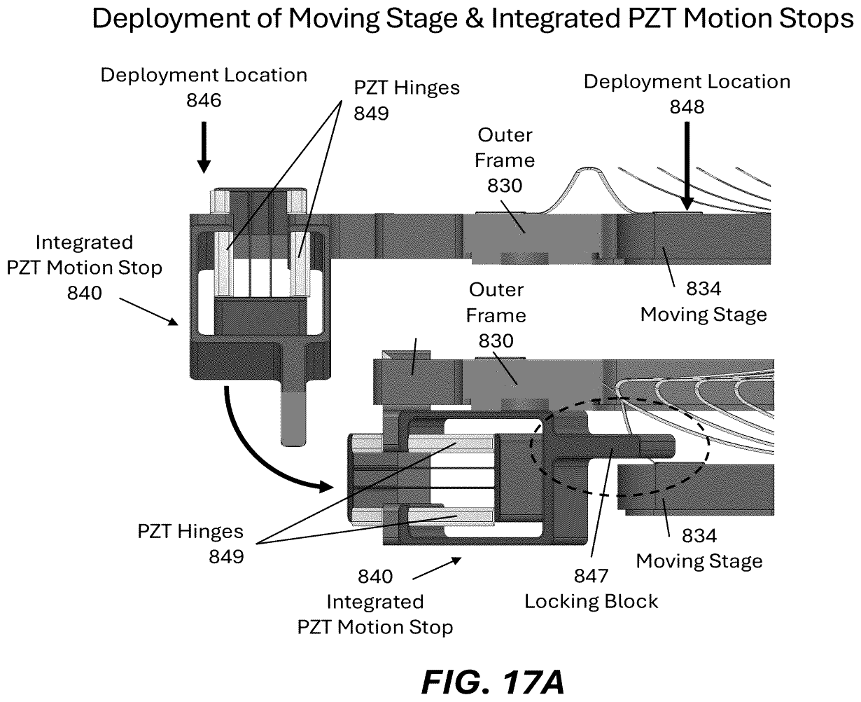

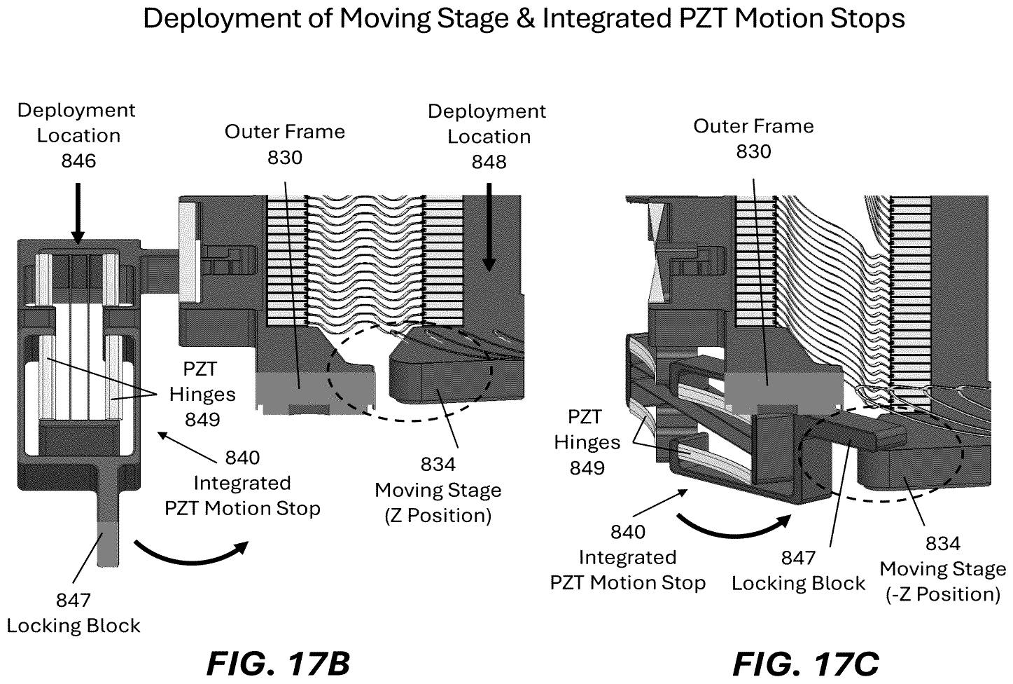

FIG. 17A shows deployment of the moving stage 834 and the integrated PZT motion stops 840, according to an example embodiment of the present disclosure. As shown in FIG. 17A, the deployment of the integrated PZT motion stops 840 can be done after placing the MEMS PZT AF actuator 824 on an assembly jig or on a raised assembly substrate. This deployment may be combined in a single assembly operation together with the deployment of the moving stage 834, which will result in the MEMS PZT AF actuator 824 moving to a “locked” condition in the negative Z travel position (−Z).

FIG. 17B shows an alternate view of the deployment of the integrated PZT motion stop 840, and FIG. 17C shows an alternate view of the integrated PZT motion stop 840 after deployment, according to the example embodiment described above with reference to FIG. 17A.

As noted above and shown in FIGS. 17A-17C, a deployment tool (not shown) can be used to push on the deployment pad 845 (at deployment location 846) to rotate the integrated PZT motion stop 840 to the deployed position. The deployment lock 842 and the deployment lock spring 843 will hold the deployment pad 845 of the integrated PZT motion stop 840 in place, while the mechanism can be reinforced by encapsulating with epoxy, as noted above.

Meanwhile, the deployment tool (not shown) can be used to push on the moving stage 834 (at deployment location 848) to hold the moving stage 834 down, while the PZT hinges 849 can be actuated to bend and thereby move the locking block 847 into the engaged (locked) position with respect to the upper surface of the moving stage 834, as shown in FIG. 17C.

### MEMS Autofocus Actuator With Integrated PZT Motion Stops

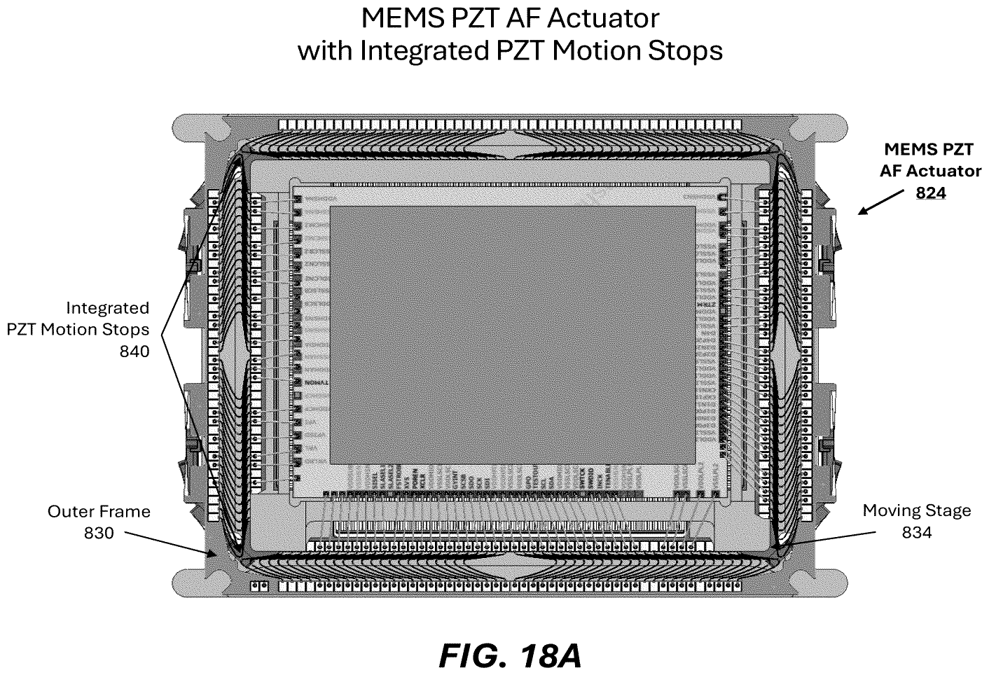

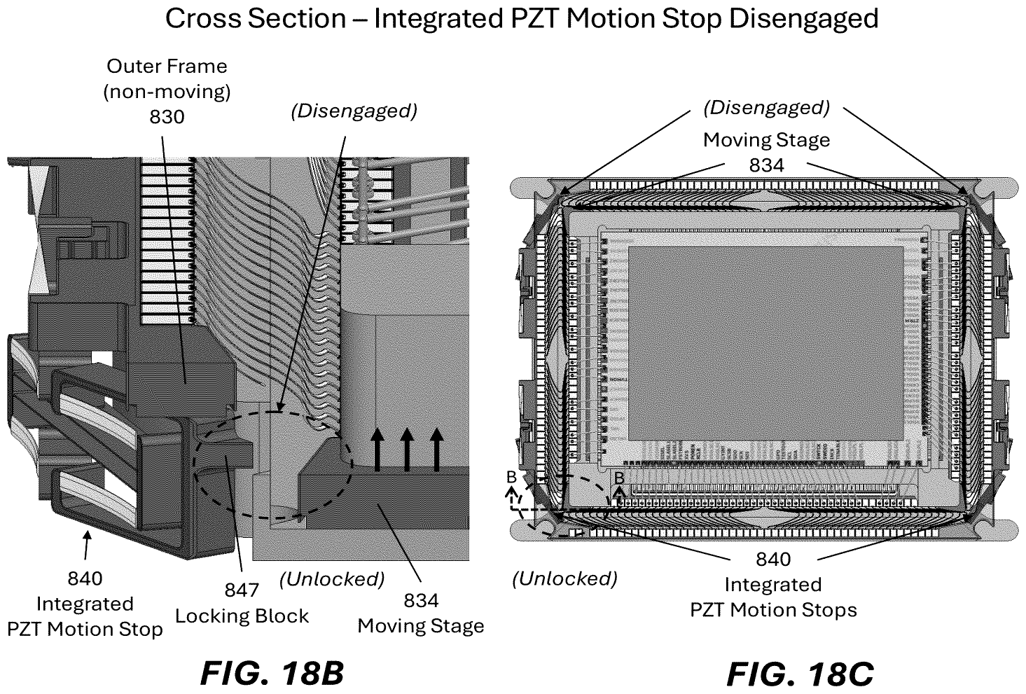

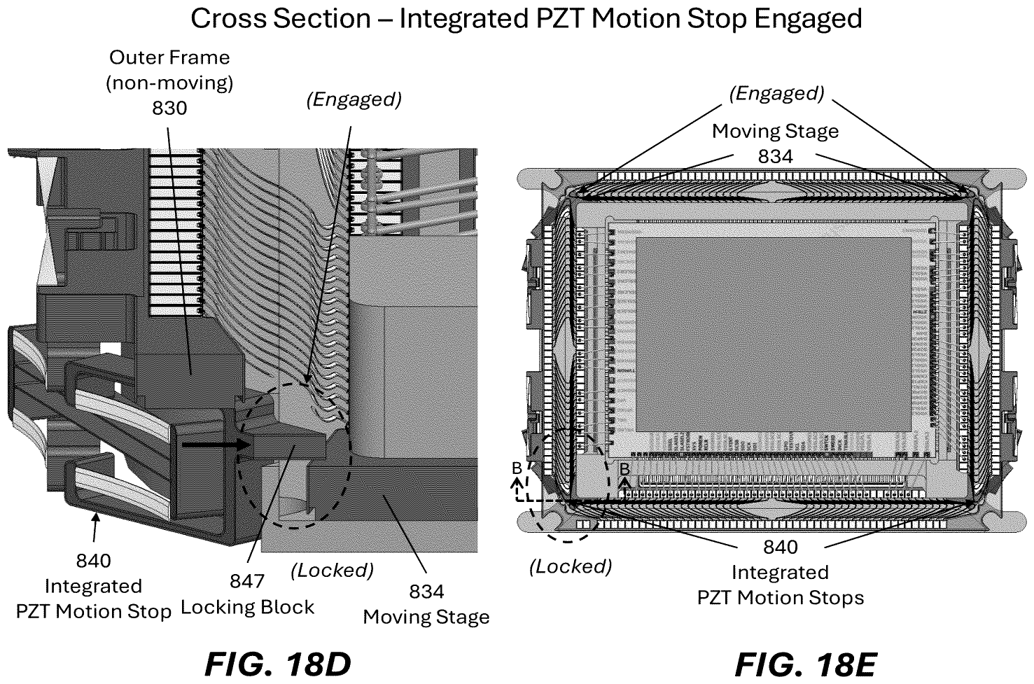

FIG. 18A shows a MEMS PZT AF actuator 824 with integrated PZT motion stops 840, as fabricated in the same MEMS chip, according to an example embodiment of the present disclosure. As shown in FIG. 18A, the MEMS PZT AF actuator 824 with integrated PZT motion stops 840 can be deployed first, and then assembled to a substrate thereafter. Alternatively, the MEMS PZT AF actuator 824 with integrated motion stops 840 can be assembled to the substrate first, and then deployed thereafter.

In the example of FIG. 18A, the moving stage 834 can be actuated to move in the out-of-plane direction along the Z-axis when the integrated PZT motion stops 840 are disengaged (unlocked), whereas such motion of the moving stage 834 in the Z-direction is limited (restricted) when the integrated PZT motion stops 840 are engaged (locked).

### Cross Section—Integrated PZT Motion Stops Disengaged

FIG. 18B is a side view and FIG. 18C is a top view, respectively, showing the integrated PZT motion stop 840 when disengaged, according to an example embodiment of the present disclosure. FIG. 18B is a cross-sectional view taken at line B-B in FIG. 18C. As shown in FIGS. 18B-18C, the MEMS moving stage 834 is free to move in the travel direction along the Z-axis while the locking block 847 of the integrated PZT motion stop 840 is in the disengaged (unlocked) position with respect to the moving stage 834.

### Cross Section—Integrated PZT Motion Stops Engaged

FIG. 18D is a side view and FIG. 18E is a top view, respectively, showing the integrated PZT motion stop 840 when engaged, according to an example embodiment of the present disclosure. FIG. 18D is a cross-sectional view taken at line B-B in FIG. 18E. As shown in FIGS. 18D-18E, after actuation of the integrated PZT motion stop 840 (by applying a voltage to bend the PZT hinges 849) the MEMS moving stage 834 is blocked (restricted) from moving in the travel direction along the Z-axis while the locking block 847 of the integrated PZT motion stop 840 is in the engaged (locked) position with respect to the moving stage 834.

### General

In general, the various operations of methods described herein may be accomplished using or may pertain to components or features of the various systems and/or apparatus with their respective components and subcomponents, described herein.

The presence of broadening words and phrases such as “one or more,” “at least,” “but not limited to” or other like phrases in some instances shall not be read to mean that the narrower case is intended or required in instances where such broadening phrases may be absent.

Additionally, the various embodiments set forth herein are described in terms of example block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

While various embodiments of the present disclosure have been described above, it should be understood that these embodiments have been presented by way of example only, and not of limitation. Likewise, the various diagrams may depict an example architectural or other configuration for the disclosure, which is done to aid in understanding the features and functionality that can be included in the disclosure. The disclosure is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present disclosure. Additionally, with regard to flow diagrams, operational descriptions and method claims, the order in which the steps are presented herein shall not mandate that various embodiments be implemented to perform the recited functionality in the same order unless the context dictates otherwise.

Although the disclosure is described above in terms of various example embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the disclosure, whether or not such embodiments are described and whether or not such features are presented as being a part of a described embodiment. Thus, the breadth and scope of the present disclosure should not be limited by any of the above-described example embodiments, and it will be understood by those skilled in the art that various changes and modifications to the previous descriptions may be made within the scope of the claims.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. A number of implementations have been described in detail with reference to various example embodiments thereof, and many modifications and variations are possible and will be apparent to those of ordinary skill in the art without departing from the scope and spirit of the disclosure, as defined in the appended claims.

What is claimed is:

1. A micro-electrical-mechanical system (MEMS) piezoelectric autofocus actuator comprising:
a fixed stage that is stationary;
a moving stage that is movable along a travel direction (Z-axis);
a motion control system coupling the fixed stage to the moving stage and comprising a plurality of motion control springs;
a plurality of piezoelectric bending elements configured to deform the motion control system and thereby control a precise position of the moving stage relative to the fixed stage; and
a plurality of integrated piezoelectric motion stops that are actuatable to restrict out-of-plane motion of the moving stage along the travel direction (Z-axis).

2. The MEMS piezoelectric autofocus actuator of claim 1, wherein the integrated piezoelectric motion stops are disposed along outer peripheral edges of the fixed stage.

3. The MEMS piezoelectric autofocus actuator of claim 1, wherein the fixed stage comprises a MEMS outer frame and a MEMS inner frame.

4. The MEMS piezoelectric autofocus actuator of claim 3, wherein the integrated piezoelectric motion stops comprise:
a motion stop subframe, wherein the motion stop subframe is integrated with the MEMS outer frame of the fixed stage;
a deployment lock spring connected to the motion stop subframe;
a deployment lock connected to the deployment lock spring;
a deployment hinge disposed on the motion stop subframe;
a deployment pad that is rotatable about the deployment hinge to a deployed position;
one or more piezoelectric hinges connected to the deployment pad; and
a locking block connected to the one or more piezoelectric hinges,
wherein the locking block is actuatable via the one or more piezoelectric hinges to restrict the out-of-plane motion of the moving stage when in the deployed position.

5. The MEMS piezoelectric autofocus actuator of claim 4, wherein the deployment lock is configured to hold the deployment pad in place when in the deployed position.

6. The MEMS piezoelectric autofocus actuator of claim 5, wherein after the deployment pad is rotated about the deployment hinge to the deployed position, the integrated piezoelectric motion stops are reinforced by applying epoxy to encapsulate the deployment lock, the deployment lock spring, the deployment hinge, a surface of the deployment pad, and at least part of a surrounding surface of the motion stop subframe.

7. The MEMS piezoelectric autofocus actuator of claim 4, wherein to restrict the out-of-plane motion of the moving stage along the travel direction (Z-axis) of the moving stage, a voltage is applied to the one or more piezoelectric hinges to actuate the integrated piezoelectric motion stops, causing the one or more piezoelectric hinges to bend and thereby move the locking block to a locked position in which the locking block engages with a surface of the moving stage to restrict the out-of-plane motion thereof.

8. The MEMS piezoelectric autofocus actuator of claim 7, wherein the MEMS outer frame has electrical contact pads disposed thereon, and the voltage is applied to the electrical contact pads disposed on the MEMS outer frame of the fixed stage to actuate the one or more piezoelectric hinges and move the locking block to the locked position.

9. The MEMS piezoelectric autofocus actuator of claim 7, wherein to allow the out-of-plane motion of the moving stage along the travel direction (Z-axis) of the moving stage, a voltage is applied to the one or more piezoelectric hinges to actuate the integrated piezoelectric motion stops, causing the one or more piezoelectric hinges to straighten and thereby move the locking block to an unlocked position in which the locking block does not engage with the moving stage to allow the out-of-plane motion thereof.

10. The MEMS piezoelectric autofocus actuator of claim 1, further comprising:
a plurality of MEMS electrical connection flexures connecting the fixed stage to the moving stage;
wherein the plurality of piezoelectric bending elements include a plurality of MEMS piezoelectric bending films.

11. A micro-electrical-mechanical system (MEMS) piezoelectric autofocus actuator comprising:
a fixed stage that is stationary;
a moving stage that is movable along a travel direction (Z-axis), wherein the moving stage has a plurality of assembly slots disposed thereon;
a motion control system coupling the fixed stage to the moving stage and comprising a plurality of motion control springs;
a plurality of piezoelectric bending elements configured to deform the motion control system and thereby control a precise position of the moving stage relative to the fixed stage;
a plurality of integrated motion limiting snubbers configured to limit in-plane motion of the moving stage;
a plurality of integrated motion stoppers configured to restrict out-of-plane motion of the moving stage along the travel direction (Z-axis); and
a plurality of assembled motion stoppers disposed in the plurality of assembly slots and configured to restrict out-of-plane motion of the moving stage along the travel direction (Z-axis).

12. The MEMS piezoelectric autofocus actuator of claim 11, wherein the integrated motion limiting snubbers comprise:
a snubber subframe, wherein the snubber subframe is integrated in a MEMS inner frame of the fixed stage;
a locking spring connected to the snubber subframe;
a locking bolt connected to the locking spring;
a twisting hinge disposed on the snubber subframe; and
a snubbing pad with a snubbing arm that is rotatable about the twisting hinge to a deployed position.

13. The MEMS piezoelectric autofocus actuator of claim 12, wherein the snubbing pad with the snubbing arm is configured to limit the in-plane motion of the moving stage when in the deployed position.

14. The MEMS piezoelectric autofocus actuator of claim 11, wherein the integrated motion stoppers comprise:
a stopper subframe, wherein the stopper subframe is integrated in a MEMS inner frame of the fixed stage;
a locking spring connected to the stopper subframe;
a locking bolt connected to the locking spring;
a twisting hinge disposed on the stopper subframe;
a stopper pad that is rotatable about the twisting hinge to a deployed position;
one or more piezoelectric hinges connected to the stopper pad; and
a Z-stop block connected to the one or more piezoelectric hinges,
wherein the Z-stop block is actuatable via the one or more piezoelectric hinges to restrict the out-of-plane motion of the moving stage when in the deployed position.

15. The MEMS piezoelectric autofocus actuator of claim 14, wherein to restrict the out-of-plane motion of the moving stage along the travel direction (Z-axis) of the moving stage, a voltage is applied to the one or more piezoelectric hinges to actuate the integrated motion stoppers, causing the one or more piezoelectric hinges to bend and thereby move the Z-stop block to a locked position in which the Z-stop block engages with a surface of the moving stage to restrict the out-of-plane motion thereof.

16. The MEMS piezoelectric autofocus actuator of claim 11, wherein the assembled motion stoppers comprise:
a stopper body that is stationary;
one or more piezoelectric hinges connected to the stopper body; and
a locking block connected to the one or more piezoelectric hinges,
wherein the locking block is actuatable via the one or more piezoelectric hinges to restrict the out-of-plane motion of the moving stage when in the deployed position.

17. The MEMS piezoelectric autofocus actuator of claim 16, wherein to restrict the out-of-plane motion of the moving stage along the travel direction (Z-axis) of the moving stage, a voltage is applied to the one or more piezoelectric hinges to actuate the assembled motion stoppers, causing the one or more piezoelectric hinges to bend and thereby move the locking block to a locked position in which the locking block engages with a surface of the moving stage to restrict the out-of-plane motion thereof.

18. A micro-electrical-mechanical system (MEMS) piezoelectric autofocus actuator comprising:
a fixed stage that is stationary;
a moving stage that is movable along a travel direction (Z-axis);
a motion control system coupling the fixed stage to the moving stage and comprising a plurality of motion control springs;
a plurality of piezoelectric bending elements configured to deform the motion control system and thereby control a precise position of the moving stage relative to the fixed stage;
an alignment substrate having a plurality of assembly slots; and
a plurality of assembled piezoelectric motion stops disposed in the plurality of assembly slots of the alignment substrate,
wherein the assembled piezoelectric motion stops are configured to be actuated to restrict out-of-plane motion of the moving stage along the travel direction (Z-axis) thereof.

19. The MEMS piezoelectric autofocus actuator of claim 18, wherein the assembled piezoelectric motion stops comprise:
a pair of electrical contact pads;
a motion stop body;
a locking block; and
a piezoelectric hinge connecting the motion stop body and the locking block,
wherein the locking block is actuatable via the piezoelectric hinge to restrict the out-of-plane motion of the moving stage.

20. The MEMS piezoelectric autofocus actuator of claim 18, wherein to restrict the out-of-plane motion of the moving stage along the travel direction (Z-axis) of the moving stage, a voltage differential is applied between the electrical contact pads to actuate the assembled piezoelectric motion stops, causing the piezoelectric hinge to bend and thereby move the locking block to a locked position in which the locking block engages with a surface of the moving stage to restrict the out-of-plane motion thereof.
